(19) United States
(12) Patent Application Publication
(10) Pub. No.: US 2026/0202591 A1
(43) Pub. Date: Jul. 16, 2026

(54) Non-Planar Metasurfaces And Related Fabrication Methods

(71) Applicant: Massachusetts Institute of Technology, Cambridge, MA (US)

(72) Inventors: Louis Marie Philippe Martin, Cambridge, MA (US); Luigi Ranno, Cambridge, MA (US); Hung-I LIN, Cambridge, MA (US); Fan YANG, Cambridge, MA (US); Tian GU, Acton, MA (US); Juejun Hu, Newton, MA (US)

(21) Appl. No.: 19/138,563

(22) PCT Filed: Dec. 15, 2023
(86) PCT No.: PCT/US2023/084452

§ 371 Date: Jun. 12, 2025

Related U.S. Application Data
(60) Provisional application No. 63/387,582, filed on Dec. 15, 2022.

(51) Int. Cl. G02B 5/18; B29D 11/00; G02B 1/04; G02B 3/00

(52) U.S. Cl. CPC G02B 5/1814; B29D 11/00769; B29D 11/00788; B29D 11/00884; G02B 1/04; G02B 3/0087; G02B 5/1852; G02B 5/1857; G02B 2207/101

(57) ABSTRACT

Methods for transferring optically active features, such as meta-atoms and diffractive elements, formed on a planar surface to a non-planar surface with high precision are described. Optical devices having meta-atoms or other diffractive features located on non-planar and/or planar surfaces can be fabricated using the described methods. Related optical systems and components are described.

### CROSS-REFERENCE TO RELATED APPLICATIONS

This application claims a priority benefit, under 35 U.S.C. § 119(e), of U.S. Application No. 63/387,582, filed on Dec. 15, 2022, and titled, “Curved, Conformal, and Hybrid Metasurfaces and Related Fabrication Methods,” which application is incorporated herein by reference in its entirety.

### STATEMENT OF GOVERNMENT RIGHTS

This invention was made with government support under HR0011-22-9-0005 awarded by the Defense Advanced Research Projects Agency. The government has certain rights in the invention.

### BACKGROUND

Optical metasurfaces, also alternatively termed sub-wavelength diffractive optics, are artificial media comprising 2-D arrays of sub-wavelength optical structures (commonly called meta-atoms). Usually, metasurfaces are fabricated on flat substrates. Several techniques have previously been explored for curved metasurface fabrication. Among these techniques are soft lithography (that can be used to directly pattern meta-atoms on curved surfaces) and pattern transfer from a rigid substrate to a flexible substrate. However, neither method is scalable, nor do they provide adequate fabrication precision for practical manufacturing.

### SUMMARY

The described technology relates to optics and optical systems, particularly metasurface optics and methods for fabricating metasurfaces on non-planar surfaces. Also described are optical systems based on non-planar metasurfaces. Such optical systems include hybrid metasurface optical systems comprising metasurfaces conformally integrated onto another optical element having a planar or non-planar surface and that may or may not include stacked layers of different optical materials. The described methods can be used to fabricate large-area metasurfaces comprising a non-planar form factor. The concepts described are applicable more generally to the field of thin-optics. Thin-optic elements include, but are not limited to, sub-wavelength optics, metasurfaces, thin-optic films and meta-optic films described below, metamaterials, diffractive optical elements (DOE), holographic optical elements (HOE), thin gradient refractive index (GRIN) optics, wafer level optics (WLO), micro-optics, etc. Thin-optic elements generally include patterned micro-scale and/or nanometer-scale features that are arranged on a substrate to provide at least one optical function (e.g., focusing, pattern formation, collimating, filtering, etc.) for light incident on the thin-optic element. A thin-optic element can have a maximum thickness no greater than 10000 times the wavelength or, in some cases, no greater than 1000 times the wavelength of light for which the thin-optic element is designed to operate. In some cases, a thin-optic element can have a maximum thickness no greater than 10 mm or, in some cases, no greater than 1 mm. The described technology can benefit a wide variety of optical applications, including imaging, sensing, endoscopy, near-eye display, eye tracking, and beyond. The ability to form non-planar metasurfaces on, for example, a curved surface and/or multi-layer material stacks imparts an additional degree of freedom for designing optical systems containing metasurfaces. Moreover, non-planar metasurfaces enable optical functions to be realized on components whose geometric shapes are dictated by non-optical considerations, for instance, aerodynamic or ergonomic factors.

Some implementations relate to methods of forming thin-optic elements (such as metasurfaces) on non-planar surfaces. Such methods can comprise acts of: forming a thin-optic element on a planar surface of a first substrate, the thin-optic element comprising a plurality of patterned features arranged on the planar surface to provide at least one optical function for light incident on the thin-optic element and having at least one specified wavelength for the at least one optical function, wherein the plurality of patterned features comprise one or both of micro-scale features and nanometer-scale features; encasing multiple surfaces of each feature of the plurality of features on the planar surface in a thermoplastic; delaminating the thermoplastic with the plurality of patterned features encased therein from the planar surface to form a thin-optic film; and applying the thin-optic film onto a non-planar surface of a second substrate.

Some implementations relate to optical devices comprising: an optically transparent substrate having a first surface and a second surface to pass light through the optically transparent substrate when the light is incident on the optically transparent substrate; and a thin-optic film adhered to the first surface of the optically transparent substrate. The thin-optic film can comprise a thermoplastic encasing multiple surfaces of each feature of a plurality of patterned features, wherein the plurality of patterned features are arranged in the thermoplastic to provide at least one optical function for light incident on the thin-optic film and having at least one specified wavelength for the at least one optical function, and wherein the plurality of patterned features comprise one or both of micro-scale features and nanometer-scale features.

Some implementations relate to a hybrid meta-optical system comprising at least one planar or non-planar metasurface and at least one planar or non-planar optical surface (e.g., a refractive, reflective, and/or diffractive optical surface) to perform at least one optical function on radiation interacting with the hybrid meta-optical system.

All combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. The terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar components).

FIG. 1A, FIG. 1B, FIG. 1C, FIG. 1D, FIG. 1E, and FIG. 1F depict example process steps to fabricate meta-atoms on curved surfaces.

FIG. 1G depicts an example of a vacuum press in which a meta-optic film is about to be applied to a non-planar optical substrate.

FIG. 1H depicts the vacuum press of FIG. 1G in which the meta-optic film is applied to and conforms to the non-planar surface of the optical substrate.

FIG. 2 depicts a hybrid meta-optical system.

FIG. 3 plots the simulated modulation transfer functions (MTFs) of the objective optics in FIG. 2.

FIG. 4A depicts another design for a hybrid meta-optical system.

FIG. 4B, FIG. 4C, and FIG. 4D plot simulated MTFs for the hybrid metasurface optical system of FIG. 4A at different wavelengths.

FIG. 5 depicts a conventional night-vision goggle optical system along with ray traces and several specifications.

FIG. 6A illustrates another design of a hybrid meta-optical system in which all surfaces are planar.

FIG. 6B and FIG. 6C plot simulated MTFs for the hybrid metasurface optical system of FIG. 6A for different infrared wavelengths.

FIG. 7A depicts an eyepiece hybrid meta-optical system integrating two non-planar metasurfaces on a curved substrate.

FIG. 7B plots the modulus of the optical transfer function for the eyepiece of FIG. 7A.

FIG. 7C depicts another implementation of an eyepiece hybrid meta-optical system integrating two planar metasurfaces on a planar substrate.

FIG. 7D plots the modulus of the optical transfer function for the eyepiece of FIG. 7C.

FIG. 8A illustrates a hybrid meta-optical system than combines flat metasurfaces with a refractive lens.

FIG. 8B, FIG. 8C, and FIG. 8D plot the modulus of the optical transfer function for the meta-optical system of FIG. 8A at different wavelengths.

FIG. 8E illustrates a hybrid meta-optical system than combines one planar metasurface with a refractive lens.

FIG. 8F plots the modulus of the optical transfer function for the meta-optical system of FIG. 8E at different ray incident angles.

FIG. 9A depicts a hybrid gradient-refractive-index (GRIN) meta-optic system comprising a flat metasurface integrated with GRIN layers.

FIG. 9B depicts a hybrid GRIN meta-optic system comprising a curved metasurface integrated with GRIN layers.

FIG. 9C depicts a hybrid GRIN meta-optic system comprising a curved metasurface integrated with GRIN layers embedding an aperture.

FIG. 10A depicts a near-eye display system integrated on a helmet comprising a flat thin-optic element that collimates and redirects an image from a projector to the viewer.

FIG. 10B depicts a near-eye display system integrated on a helmet comprising a curved thin-optic element conformally integrated onto the helmet visor that redirects an image from an intermediate plane towards the viewer.

FIG. 10C depicts a near-eye display system integrated on a helmet comprising multiple thin-optic elements integrated onto the helmet visor that redirect an image towards the viewer.

FIG. 10D depicts a near-eye display system integrated on a helmet comprising multiple thin-optic elements and projectors integrated with the helmet visor.

FIG. 10E depicts a near-eye display system integrated on a helmet having a projector illuminating from the inside of the helmet.

FIG. 11A depicts a meta-optic projector (or meta-optic imager) that provides image projection (or image acquisition) with a panoramic FOV and high resolution using a flat meta-optic with metasurfaces.

FIG. 11B and FIG. 11C depict alternative implementations of meta-optic projectors (or meta-optic imagers) that provide image projection (or image acquisition) with a panoramic FOV and high resolution using a curved meta-optic with metasurfaces.

FIG. 12 depicts a near-eye display system integrated within a helmet having a meta-optic projector illuminating from the inside of the helmet.

FIG. 13A depicts a near-eye display system integrated on a helmet with embedded arrays of wide-angle meta-optic projectors using flat substrates on which the metasurfaces are located.

FIG. 13B depicts a near-eye display system integrated on a helmet with embedded arrays of wide-angle meta-projectors using curved substrates on which the metasurfaces are located.

FIG. 14A depicts a near-eye display system that integrates meta-optic projectors and meta-optic imagers comprising flat substrates for eye-tracking devices.

FIG. 14B depicts a near-eye display system that integrates meta-optic projectors and meta-optic imagers comprising curved substrates for eye tracking devices.

FIG. 15 illustrates example process steps to transfer optically-active features patterned on a flat substrate to a non-planar surface of another substrate.

FIG. 16 includes a microscope image (larger image) and scanning-electron micrograph (inset) of meta-atoms transferred from a flat surface to a non-planar surface following the process steps of FIG. 15.

FIG. 17A and FIG. 17B plot results from mechanical deformation studies of micro-scale patterned features transferred from a flat surface to a non-planar surface following the process steps of FIG. 15.

FIG. 18A illustrates an example of a hybrid meta-optical system in which a metasurface is combined in the system with a binary optic element.

FIG. 18B illustrates an example of a hybrid meta-optical system in which a metasurface is combined in the system with a multi-level optic element.

### DETAILED DESCRIPTION

### 1. Introduction

The technology described herein relates to non-planar metasurfaces and fabrication approaches that leverage industry-standard manufacturing techniques to form metasurfaces on planar and non-planar surfaces. For some implementations, a non-planar surface is a smoothly varying curved surface (e.g., a spherically convex or concave surface, a cylindrically convex or concave surface) and the radius of curvature of the surface can be as small as 10 mm in some cases, or as small as 1 mm in some cases. For some implementations, a non-planar surface is piecewise continuous over a convex or concave surface (e.g., such as the outer surface of a hexagonal rod or other polygonal rod or a geodesic dome). For some implementations, a non-planar surface is a stepwise multi-level surface or multi-layer surface, as described further below. For some implementations, a non-planar surface is a freeform surface which can comprise undulations in multiple directions or a combination of other non-planar surfaces mentioned above.

Different structures can result from patterning meta-atoms on non-planar surfaces. Resulting structures include curved meta-optical devices comprising at least one metasurface disposed on an optical component having curvature on both sides (e.g., a dome or a shell type structure). Resulting structures include conformal meta-optical devices comprising at least one metasurface disposed on a non-planar side of optical component. The other side of the optical component can be flat (such as a plano-convex lens). Resulting structures include 2.5D meta-optical devices comprising a combination of 2D planar and 3D non-planar elements; or multi-layer or multi-level structures extending out of the 2D plane (e.g., a GRIN or a multilevel DOE structure).

The fabrication approaches are also applicable to producing other types of microstructures, e.g., diffractive optical elements, gratings, waveguides, photonic integrated circuits, MEMS, etc. with a curved, conformal, and/or multi-layer form factor. Also described are several meta-optical systems that include planar and/or non-planar metasurfaces. Such meta-optical systems can be implemented as hybrid meta-optical systems that combine planar and/or non-planar metasurfaces with at least one other optical element having at least one planar or non-planar surface. The other optical element(s) can comprise a refractive optical element, reflective optical element, and/or a diffractive optical element (DOE). In some cases, at least one of the other optical elements (such as a DOE) can comprise a multi-level optical element having multiple levels of patterned features. The hybrid meta-optical system can include multi-layer material stacks within the system. The meta-optical devices described herein can be used for applications in imaging, sensing, near-eye display, and endoscope systems, for example.

Meta-optical devices described herein are based on metasurfaces. A metasurface comprises a collection of so-called meta-atoms arranged in close proximity to one another (e.g., disposed on a surface of a substrate or encased in a thin polymer film). The meta-atoms are arranged to provide at least one optical function (e.g., focusing, pattern formation, filtering, collimating, aberration correction, etc.) for light incident on the metasurface having a specified wavelength or range of wavelengths for performance of the optical function(s). The meta-atoms of a metasurface can all have the same shape (e.g., silicon pillars) or have different shapes, some of which are described below. The meta-atoms can comprise microscale structures (sizes on the order of 100 nanometers to 10 microns) and/or nanoscale structures (sizes on the order of 100 nanometers or less). The meta-atoms can be sub-wavelength in size and/or include sub-wavelength features sizes, where the wavelength is the wavelength of radiation for which the meta-optical device is to be used. The meta-atoms can be formed from a metal, semiconductor, and/or insulator that can be patterned using microfabrication processes.

It is a combination of meta-atom parameters-the arrangement of meta-atoms (e.g., spacing and layout of meta-atom locations), meta-atom size, meta-atom material, and meta-atom shape—that give a meta-surface its optical functionality or functionalities. The superposed light interactions with the meta-atoms determine the resulting optical functionality or optical functionalities. One skilled in the art of optical modeling can construct numerical models to represent the optical behavior of a metasurface and use the numerical models to design a metasurface to provide one or more desired optical functionalities. Such optical modeling is similar to modeling the beam modulating behavior (e.g., focusing) of a diffractive optical element or Fresnel lens having sub-wavelength features, however, the metasurface can provide more advanced optical functionality due to the number of different parameters of the meta-atoms that can be controlled. For example, a metasurface can provide optical functionality that is selectively dependent on only polarization, only wavelength, or only angle of incidence, for example, or dependent on some combination of these optical attributes.

The concepts relating to forming non-planar metasurfaces are applicable to thin-optic elements, a class of optical elements which includes meta-optic elements as described further below. Thin-optic elements can comprise a plurality of patterned features (e.g., optically diffractive features) arranged on a surface to provide at least one optical function for light incident on the thin-optic element. The light has at least one specified wavelength for performance of the at least one optical function by the thin-optic element. The features of the thin-optic element can be transferred from a planar surface to a non-planar surface in the same way that meta-atoms formed on a planar surface can be transferred to a non-planar surface. All optical systems and components described in this invention can be used bi-directionally. For example, a given optical system can be used for imaging or sensing when the optics is coupled with an image sensor. Alternatively, the same optical system can be used for image or pattern projection when the image sensor is replaced by a light source (e.g., one or more light emitting devices such as LEDs or an image source such as a micro-display).

### 2. Conformal Metasurface Optical Fabrication Process

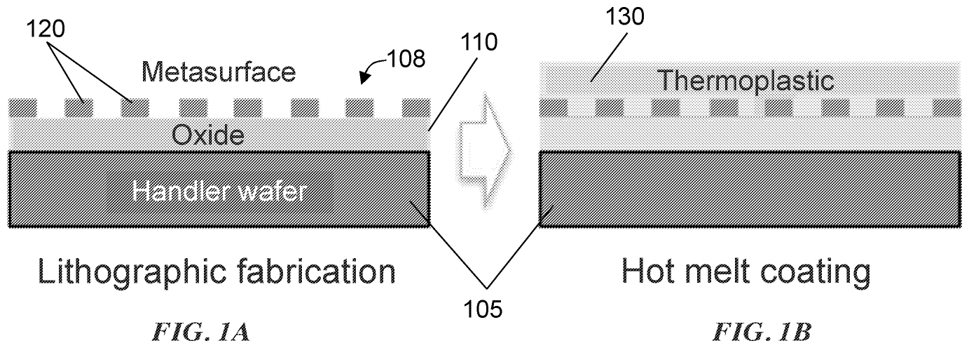

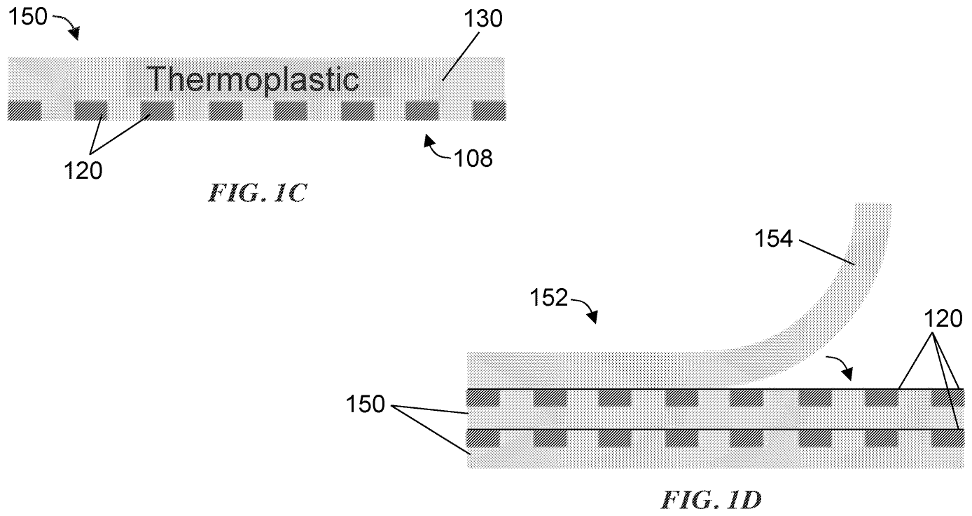

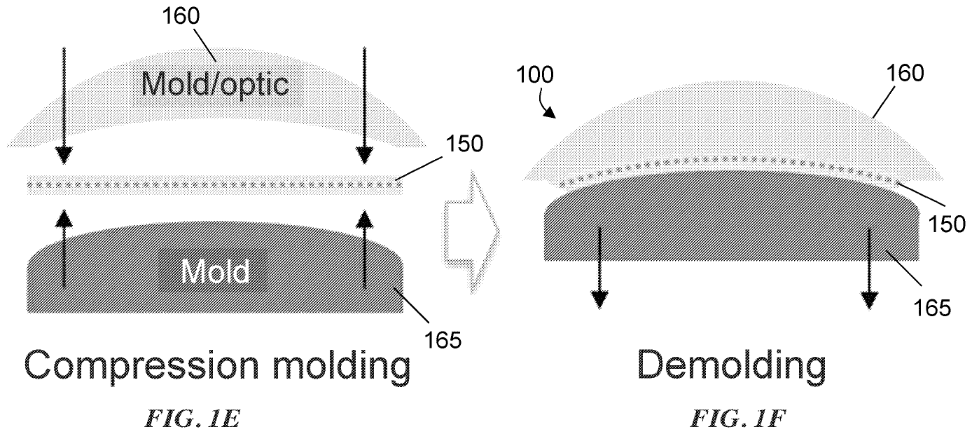

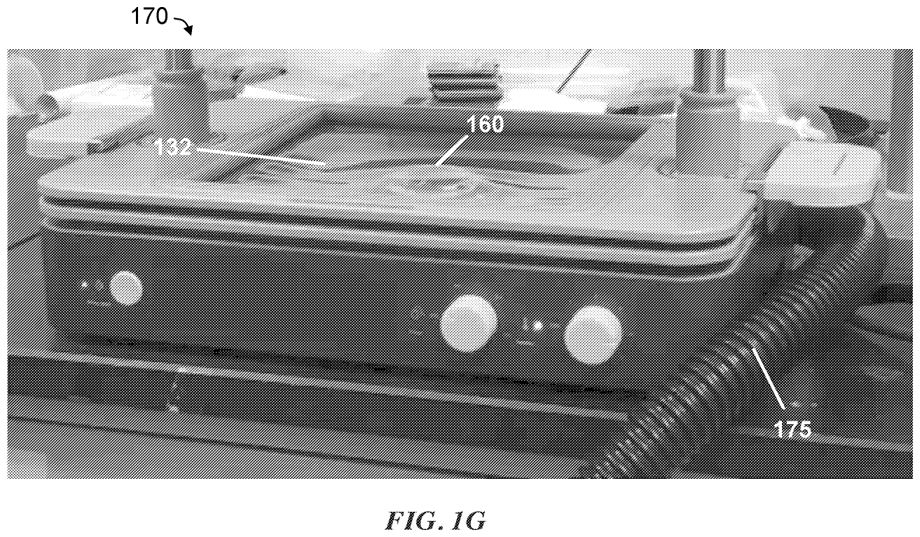

FIG. 1A through FIG. 1F depicts one embodiment of a process to fabricate a non-planar, metasurface optical device 100 (shown in FIG. 1F) having meta-atoms 120 disposed on one or more non-planar surfaces (e.g., curved surfaces). An example process can start with fabrication of meta-atoms 120 on a handler substrate 105 using deep UV lithography, electron beam lithography, nanoimprint, nanostencil lithography or other patterning techniques. For the illustration of FIG. 1A, a plurality of meta-atoms 120 are disposed on a planar surface to form a planar metasurface 108.

The planar metasurface 108 can be disposed on a sacrificial layer 110. The sacrificial layer 110 (an oxide layer in this example) can be formed on the handler substrate 105 such as a handler wafer (e.g., a full silicon wafer). In some cases, the handler substrate 105 can serve as the sacrificial layer. The sacrificial layer 110 can subsequently be removed (e.g., etched away or mechanically removed by lapping, polishing, or dicing) to release the meta-atoms 120 from the handler substrate 105. In the illustrated example process, a thermoplastic 130 can be applied in liquid or molten form to the planar metasurface 108 to form a film that encases the meta-atoms 120, as depicted in FIG. 1B. The thermoplastic film can be optical quality in some cases and may have a surface that is not optical quality in some implementations when transferred to another surface. A surface that is not optical quality may be made optical quality by recoating the surface with another material having a similar refractive index. When encasing the meta-atoms 120, the thermoplastic 130 contacts more than one surface of the meta-atoms (e.g., at least two surfaces that are at an angle to each other, at least four surfaces of a cube-shaped meta-atom, etc.). In some implementations, the thermoplastic 130 contacts all surfaces of the meta-atoms that do not contact the underlying substrate. The thermoplastic 130 can be optically transparent or exhibit low optical loss (e.g., less than 20 % optical attenuation). In some cases, the thermoplastic 130 can be coated through a solution-based process (e.g., by first dissolving the thermoplastic in a solvent and then performing spin coating, spray coating, or dip coating). Alternatively, a hot melt coating process can be used, where the thermoplastic 130 is heated to above its glass transition temperature so that it can flow and form a coating layer over the meta-atoms 120. The glass transition temperature of the thermoplastic 130 can be well below the melting temperature of the material from which the meta-atoms 120 are formed (e.g., an inorganic material such as silicon and/or an oxide).

The thermoplastic 130 is a material that can soften and flow when heated above its glass transition temperature and return to a rigid solid without any degradation of the plastic when cooled below its glass transition temperature. Examples of thermoplastics that can be used for transfer the planar metasurface 108 include, but are not limited to, polyester, polystyrene (PS), polycarbonate (PC), polypropylene (PP), acrylics, polyethylene (PE) polyethylene terephthalate (PET or PETE), polyethylene terephthalate glycol (PETG), polyvinyl chloride (PVC), acrylonitrile butadiene styrene (ABS), polyether ether ketone (PEEK), polyimide, and polyamides. The thermoplastic 130 can be deposited to a thickness in a range from 0.1 microns to 500 microns, though thicker layers may be used in some cases. In some implementations, a more mechanically stable, thicker, yet flexible, film (e.g., polydimethylsiloxane (PDMS)) can be temporarily adhered to the thermoplastic layer prior to delamination of the thermoplastic layer to aid in handling of the thermoplastic layer.

After the thermoplastic 130 hardens, the sacrificial layer 110 can be etched away to release the thermoplastic 130 and meta-atoms 120 as a free-standing meta-optic film 150, which is depicted in FIG. 1C. The meta-optic film 150 can also be referred to more generally as a thin-optic film. In another approach, mechanical removal (e.g., lapping, polishing, or dicing) and/or etching of the handler substrate 105 can be carried out to form the free-standing meta-optic film 150. When the handler substrate 105 is removed by mechanical removal and/or etching, a sacrificial layer 110 may be omitted. The thermoplastic 130 can retain the spacing between the meta-atoms of the metasurface 108 after the meta-atoms 120 are released from the handler substrate 105. Because the thermoplastic 130 is flexible and can be made more flexible by heating, the meta-optic film 150 can then be applied to a non-planar surface. In some cases, multiple meta-optic films 150 can be stacked and bonded together to form a flexible, multilayer meta-optic film 152, as depicted in FIG. 1D.

Stacking of meta-optic films 150 can create optically-coupled bi-layer or multi-layer metasurfaces to, for instance, boost optical dispersion engineering. In such cases, two meta-optic films 150 can be stacked with their metasurface sides (comprising meta-atoms 120) facing each other. Stacking of meta-optic films 150 can also form a multi-functional optical device comprising multiple, functionally-different and independent metasurface layers. In such implementations, the meta-optic films 150 can be stacked such that at least one metasurface side of one film faces away from the adjacent film in the stack, so that there is a space between the metasurface sides (and meta-atoms 120) of the different meta-optic films, as depicted in FIG. 1D. In some cases, a bare thermoplastic film 154 may be inserted as a spacer between or adjacent to metasurfaces. In some implementations, the bare thermoplastic film 154 can be applied over a metasurface side of a film (as depicted in FIG. 1D) to protect the meta-atoms 120 or space them from a surface to which the meta-optic film(s) 150 will be applied.

Compared to existing multilayer metasurface fabrication methods based on elastomers (such as silicone), the mechanical rigidity of the thermoplastic (130) at room temperature facilitates the stacking step and may allow precise interlayer alignment with deep sub-micron accuracy, similar to the wafer bonding process in 3-D or 2.5-D integrated circuits. Removal and transfer of a polymer membrane can be simpler compared to repeated multilayer lithography and “planarization,” particularly on a non-planar surface.

The meta-optic film 150 can be subsequently compression molded with at least one mold 165 to the final non-planar surface. Such compression molding is depicted in FIG. 1E and FIG. 1F. The meta-optic film(s) 150 can be heated during compression molding to allow the film to deform and cooled once molded into its final shape. After the meta-optic film 150 is molded (e.g., onto the surface of an optic 160 or molded to its final shape if two molds are used instead of molding onto an optic 160), the mold(s) 165 can be removed to leave a non-planar, metasurface optical device 100. The non-planar, metasurface optical device 100 can comprise only the molded, non-planar meta-optic film 150 in some cases, or can comprise one or more meta-optic films 150 molded to and adhered to the surface of an optic 160 (such as an optical lens, window, filter, wave plate, prism, grating, etc.) or other surface.

In some cases, the meta-atoms 120 can be bonded to the surface of the optic 160 (or surface to which the meta-optic film 150 is applied) and the thermoplastic 130 can be etched or dissolved away. For example, the meta-atoms 120 can come into direct contact with the surface of the optic 160 and optically contact bond to the optic 160. In some cases, heat can be applied to bond the meta-atoms 120 to the surface (e.g., sintering). In another approach a thin layer of adhesive can be used to bond the meta-atoms 120 to the surface of the optic 160. In some implementations, the thermoplastic 130 bonds the meta-atoms 120 to the surface of the optic 160 or other surface.

One skilled in the art can appreciate that other thermoforming or molding methods can also be used in place of compression molding in this step. For example, a vacuum press 170 shown in FIG. 1G and FIG. 1H can be used to shape the meta-optic film 150 or multi-layer meta-optic film 152. In FIG. 1G, an optic 160 is placed in the vacuum press 170 and a thermoplastic film 132 is sealed in the vacuum press 170 over the optic 160. The thermoplastic film 132 is heated and a vacuum applied to the press through the vacuum tube 175. The applied vacuum pulls the thermoplastic film 132 over the optic 160 as shown in FIG. 1H. The thermoplastic film 132 retains the shape of the optic's curved outer surface when cooled.

The inventors have found that it can be beneficial to invert the vacuum press 170 such that the applied vacuum pulls the thermoplastic film 132 upward against gravity and onto the optic 160. The thermoplastic film 132 can be supported from below by a polymer mesh (not shown in the drawings) such that the thermoplastic film 132 can be heated uniformly without drooping or distorting before the vacuum is applied. Further, the rate of applying the vacuum can be carefully controlled to avoid sudden and uneven changes in pressure across the thermoplastic film 132. Such an arrangement can reduce distortion of the metasurface when molded onto the optic 160.

When making a non-planar, metasurface optical device 100, a refractive, reflective, or diffractive optic 160 can act as mold in addition to providing optical functionality for the resulting optical device 100. Such a non-planar, metasurface optical device 100 may be referred to as a non-planar hybrid meta-optic device and can comprise one or more metasurfaces conformally covering at least a portion of the non-planar refractive optical surface.

The processes of making non-planar, metasurface optical devices 100 described above can exploit industry-scale thermoplastic forming (TPF) processes (e.g., melt coating, lamination and thermoforming or molding) to enable large-area scalable manufacturing. The known advantage of TPF for precise geometry definition and the well-established TPF modeling methodology can allow prediction and control of meta-surface deformation throughout the process. For example, the layout pattern of meta-atoms (or thin-optic features) that will be fabricated on the handler substrate 105 can be pre-distorted to compensate for and cancel later distortions that would otherwise be caused by deformation of the thermoplastic sheet when transferred onto the curved surface.

### 3. Hybrid Meta-Optic Devices

The basic architecture of the hybrid meta-optic device (which may be referred to more generally as a hybrid thin-optic device) comprises a substrate and at least one meta-optic film 150 (or thin-optic film) integrated with the substrate. The substrate of a hybrid meta-optic device can be a refractive optic 160 as described above, or a reflective optic or a diffractive optic, though other optical substrates can be used. In some cases, the hybrid meta-optic device can comprise more than one optic 160 (e.g., a stack of optics), one or more of which can be integrated with one or more meta-optic films 150. The substrate may be initially flat (for a planar hybrid meta-optic device) or curved or in a freeform shape (for a non-planar hybrid meta-optic device). In some cases, the substrate comprises multiple layers. The substrate may be optically transparent and may be designed to perform a refractive and/or diffractive optical function (e.g., focusing, diverging, spectral separation, etc.). Some implementations of hybrid meta-optic devices can further include one or more photodetectors and/or one or more light sources integrated with the hybrid meta-optic device.

A hybrid meta-optic device as described herein can further comprise one or more additional thin-optic elements. Examples of thin-optic elements include sub-wavelength optics, metasurfaces, meta-optic films 150, metamaterials, diffractive optical elements (DOE), holographic optical elements (HOE), gradient index (GRIN) optics, wafer level optics (WLO), micro-optics, etc. The thin-optic elements can be patterned and transferred to a planar or non-planer hybrid meta-optic device using the TPF techniques as described above in connection with FIG. 1A through FIG. 1H. The thin-optic element may be positioned on, inside, outside, conformally, or in proximity to the substrate of a hybrid meta-optic device. In some cases, light is coupled by the hybrid meta-optic device into a photodetector or from a light source. To accommodate for the geometric deformation, the unit structures (e.g., sub-wavelength arrayed meta-atoms in the case of metasurfaces) are designed and configured according to the substrate shape to provide the target optical functionality and quality. Multiple thin-optic elements may be used in a hybrid meta-optic device.

The conformal thermoplastic film integration processes allow the assembly of one or multiple meta-optic films 150 onto a same substrate. For instance, thin-optic elements, apertures, shadow masks, filters, transmissive coatings, and/or reflective coatings can be integrated or patterned on or in one or more thermoplastic films and stacked with other layers on the substrate. Apertures may be used to confine the spatial and/or angular extent of an optical beam. Reflectors or reflective metasurfaces may be employed to fold a beam between certain layers to reduce the overall thickness of the optical system. Index contrasts of the different layers can also be employed to enable beam folding via total internal reflection (TIR). The 3D multi-layer material stacks therefore effectively serve as an optomechanical integration platform. The fabrication processes are scalable to larger substrates (e.g., 50-mm-diameter optics). Next described are several embodiments, variations, designs and applications of the hybrid optical devices.

### 4. Hybrid Imaging and Eyepiece Optics

Hybrid meta-optical devices can be used in imaging, sensing, display and eyepiece optics (e.g., night vision goggles (NVG), virtual/augmented reality (AR/VR) systems, etc.) as described in this section.

A traditional NVG objective lens usually has a field-of-views (FOV) of approximately 40° and typically includes more than six refractive lenses with an overall system aspect ratio (length/aperture diameter) over 2:1, both of which further increase with growing FOV and resolution requirements. Integrated with the eyepiece and image inverter, the overall aspect ratio of a traditional NVG optical system is usually over 6:1, resulting in relatively large torque load on the wearer.

While flat optics (planar metasurfaces or DOEs) have been acclaimed as an alternative to traditional bulk optics with considerable size, weight, and power advantages, they have noticeable chromatic and Seidel aberrations in large-aperture systems. Current achromatic metalenses rely on dispersion engineering of meta-atoms, an approach facing fundamental constraints in aperture size due to limited accessible group delay. A zone engineering approach has also been exploited recently, although it faces a similar trade-off between performance (efficiency in particular) and lens aperture size due to destructive interference between increasing number of zones. Moreover, inter-coupling between meta-atoms, which has long been ‘an elephant in the room’ in the metasurface community, becomes significant and strongly wavelength-dependent for octave-spanning operation. An alternative approach resorts to optimized arraying of diffractive elements, which however is subjected to a trade-off between aperture size and numerical aperture (NA), since multi-level diffractive elements only provide a fixed 1/λ dispersion behavior. Inverse design via full-aperture optimization, on the other hand, is computationally prohibitive for centimeter-sized optics.

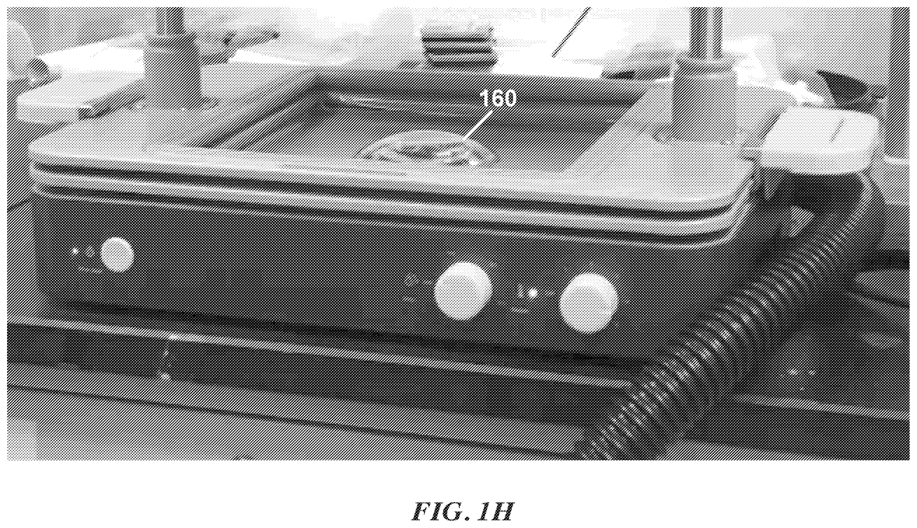

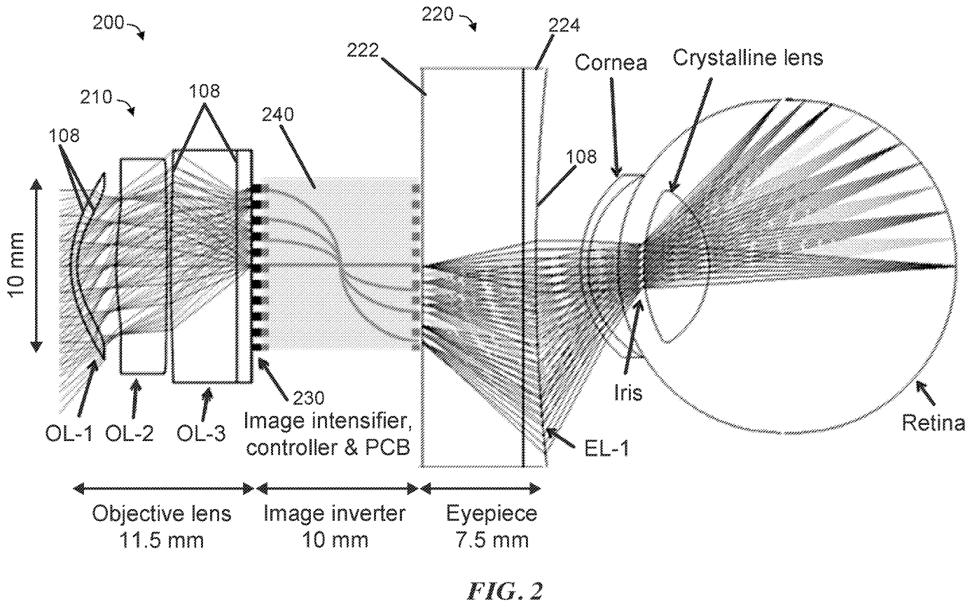

FIG. 2 depicts a hybrid meta-optical system 200 that combines refractive and metasurface optics and can resolve the above challenges with aberrations as the refractive component(s) can offer the large true group delay to address chromatic aberration while the metasurface(s) can correct the Seidel aberrations effectively. Results from a ray trace simulation are shown. In this example, the objective optic 210 and eyepiece optic 220 combined consists of only four optical elements, yielding a total length of less than 3 cm and an ultralight weight of 11 grams while achieving unprecedented performance.

The hybrid meta-optical system 200 comprises an objective optic 210 having three objective sub-lenses (OLs). OL-1 and OL-3 are hybrid lenses with a metasurface 108 on each side of a refractive lens, while OL-2 is a pure refractive lens. The metasurfaces 108 can be different from each other (e.g., have different meta-atom patterns). The meta-atoms are too small to be visible in FIG. 2. One or more of the metasurfaces 108 can be implemented with a meta-optic film 150 described above. OL-3 has a flat back surface to facilitate integration and bonding to the image intensifier 230. In one example, one or more lenses in the hybrid meta-optical system 200 are freeform lenses made of BaF₂. In other examples, the lenses may be made of silica, polymers, and other conventional optical materials. The metasurfaces 108 each consist of an array of subwavelength structures (i.e., meta-atoms). Example meta-atom geometries include pillars, disks, squares, bars, rings, fins, ridges, H-shapes, “+” shapes, freeform structures, etc.

After the image is converted to one or more visible colors by the image intensifier 230, a fiber optic inverter 240 (twister) is used to invert the re-emitted image for display by the eyepiece optic 220. In a distance equal to the image size (a 1:1 aspect ratio), the fiber optic inverter 240 is an efficient and compact way to invert an image. Commercially-available fiber inverters 240 can have core sizes down to 4 μm, allowing scaling of the resolution up to 128 lp/mm. Other types of optical systems (e.g., metasurface optics) may also be used as an image inverter.

The eyepiece optic 220 comprises a concave lens 224 having a metasurface 108 integrated on a curved surface. The concave lens 224 is bonded to a flat polymer or glass spacer 222 (e.g., made of E48R). In one example, the eyepiece optic 220 provides high-quality image projection from the fiber-optic inverter towards the eye for both red and amber colors with an ultra-compact design (e.g., no greater than 7.5 mm overall length along an optical axis of the system). When the eyepiece optic 220 is used in an AR/VR system, a micro-display may be used to replace the fiber-optic inverter 240 and its image projected by the eyepiece optic 220 towards the eyes. Alternatively, an image may be relayed to the focal plane of the image inverter 240 via other optical components and then projected by the eyepiece optic 220 towards the eyes.

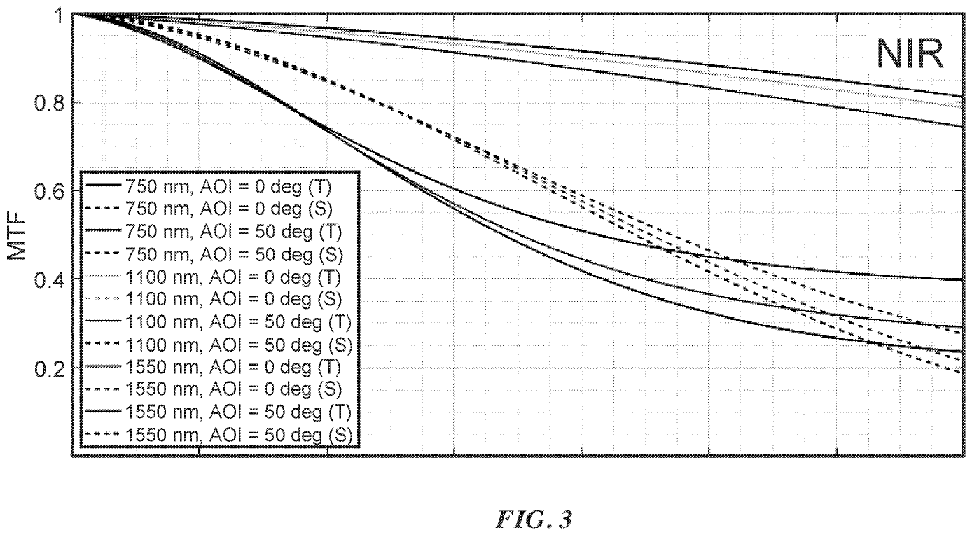

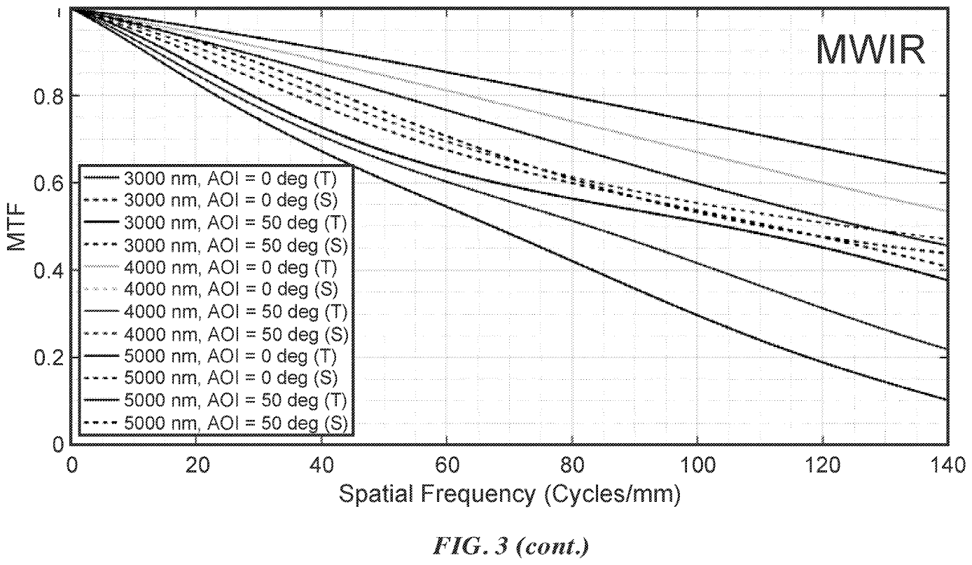

FIG. 3 plots the simulated modulation transfer functions (MTFs) of the objective optic 210 in FIG. 2. The plots are for both tangential (T) and sagittal(S) rays. Within a 100° FOV at NIR, the objective optic 210 achieves a resolution of >140 lp/mm. Across the mid-wave infrared (MWIR) band (3000-5000 nm), the objective optic 210 attains a near-diffraction-limited resolution of >110 lp/mm. If only two hybrid meta-optic lenses are used (i.e., OL1 and OL3, omitting OL2), the resulting objective optic can still be engineered to achieve a resolution of >70 lp/mm for both near-infrared (NIR) and mid-infrared (MIR) bands over a 100° FOV.

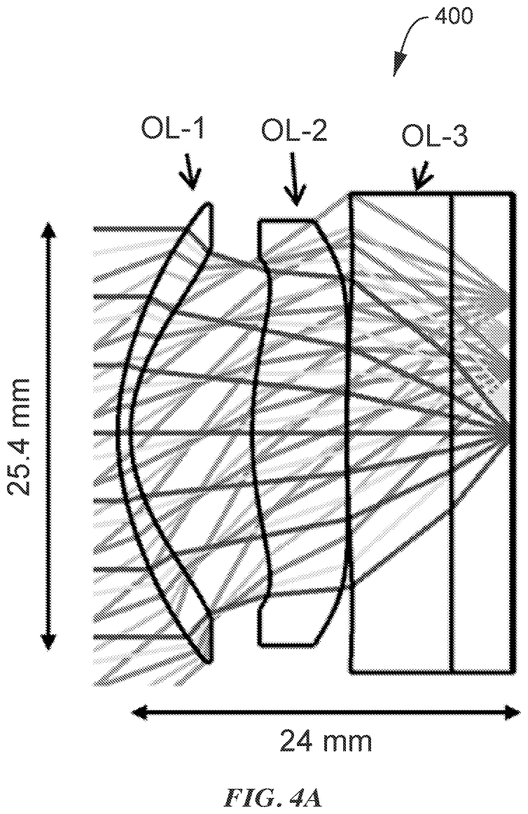

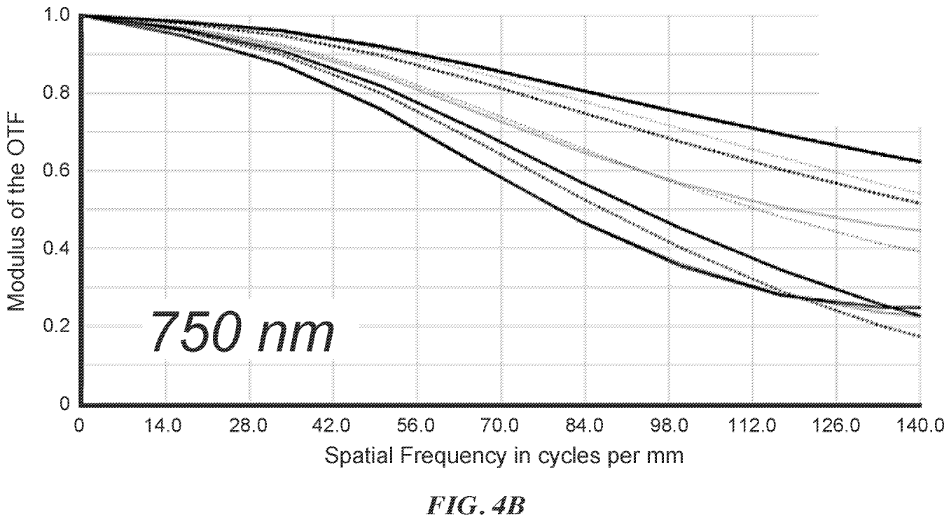

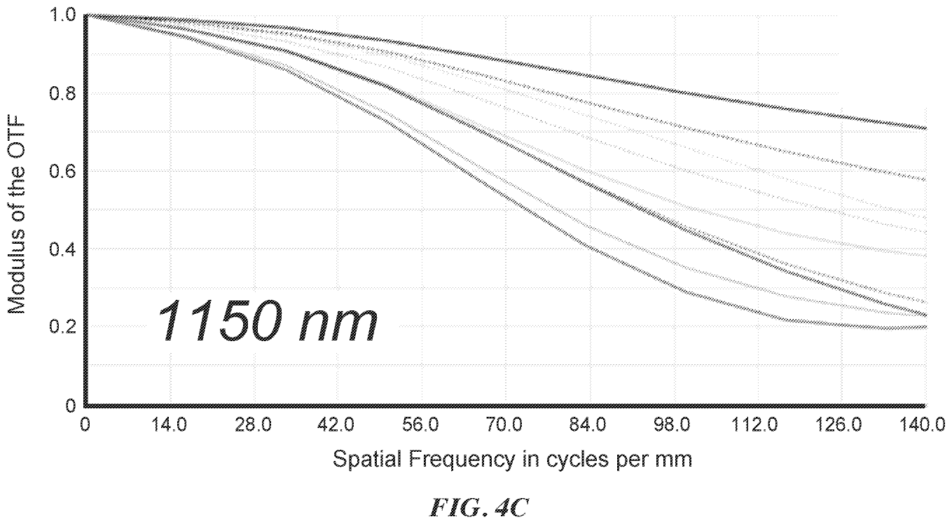

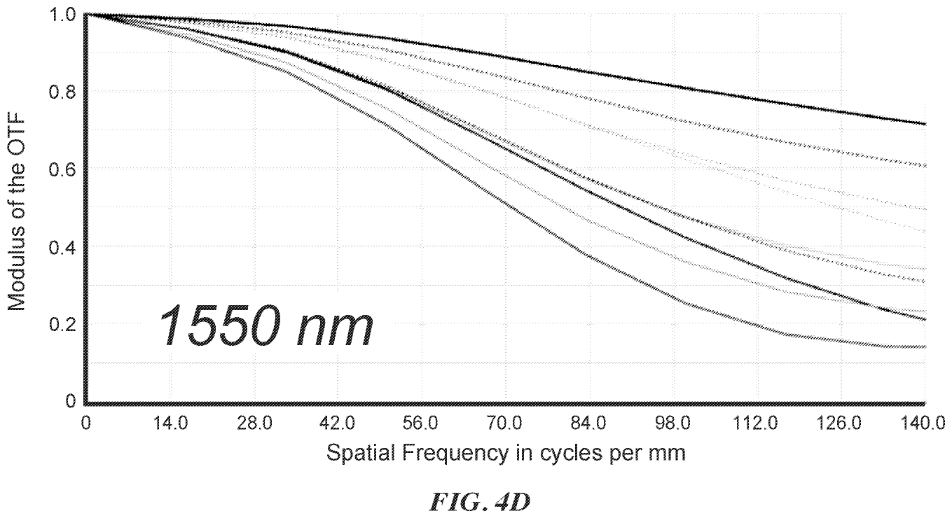

FIG. 4A depicts another design for a three-lens hybrid meta-optical system 400 that can be compared against a conventional eight-lens optical system 500 shown in FIG. 5. MTFs are plotted in FIG. 4B, FIG. 4C, and FIG. 4D for wavelengths at 750 nm, 1150 nm, and 1550 nm, respectively. For the hybrid meta-optical system of FIG. 4A, the input aperture is increased to 25 mm and conformal metasurfaces 108 are similarly positioned on either curved or planar optical surfaces of hybrid meta-optic lenses OL-1 and OL-3. The example design consists of three optical elements: the two hybrid meta-optic lenses (OL-1 and OL-3) with metasurfaces 108 on the two opposing surfaces of each lens and one refractive-only lens (OL-2). The total track length is less than 24 mm (aspect ratio<1:1). The design yields an FOV over 80° with a resolution of >130 lp/mm. The focal spot radii are kept between 1 μm and 6 μm over the entire FOV.

A comparison is made between the hybrid metasurface optical system of FIG. 4A and an existing legacy NVG objective lens design shown in FIG. 5. The legacy design consists of eight glass lenses with an input aperture diameter of ~23 mm and a total track length of 46 mm (aspect ratio of 2:1). The design achieves a field-of-view of 40° with a resolution of 40 lp/mm. As the incident angle increases, the focal spot size grows by more than 6 times, from a radius of 4 μm at normal incidence to 27 μm at a 19° incident angle. Therefore, compared to the traditional NVG design, the hybrid metasurface optical system of FIG. 4A offers:
~2× expanded FOV, close to natural eyesight;
over 3× improvement in resolution;
2× reduction in total length; and
2× reduction in optical element count.

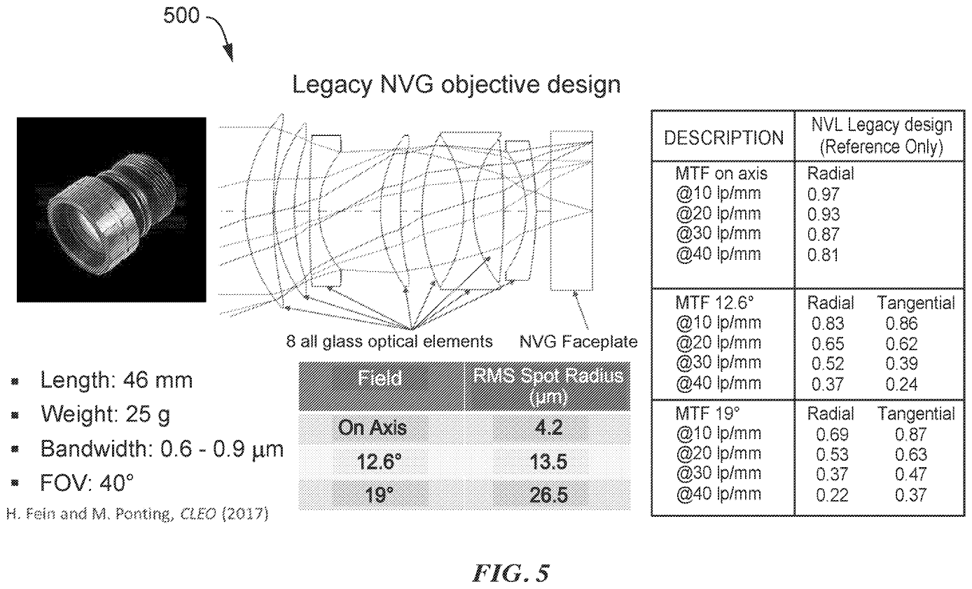

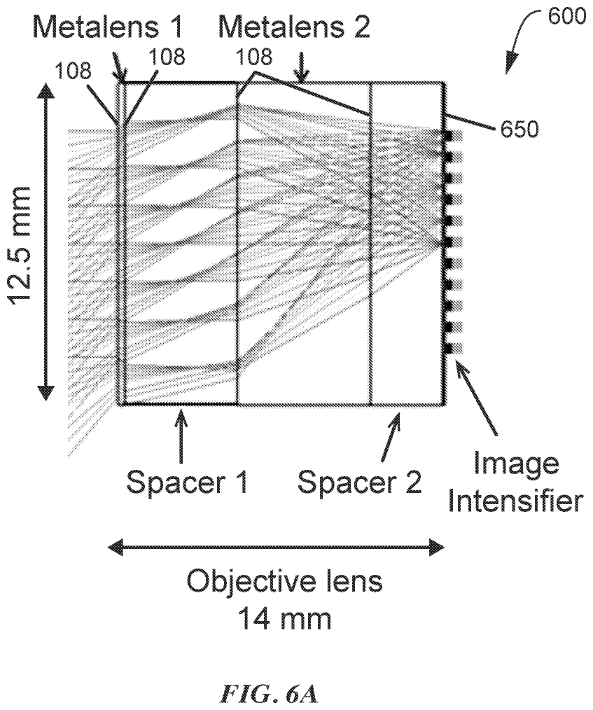

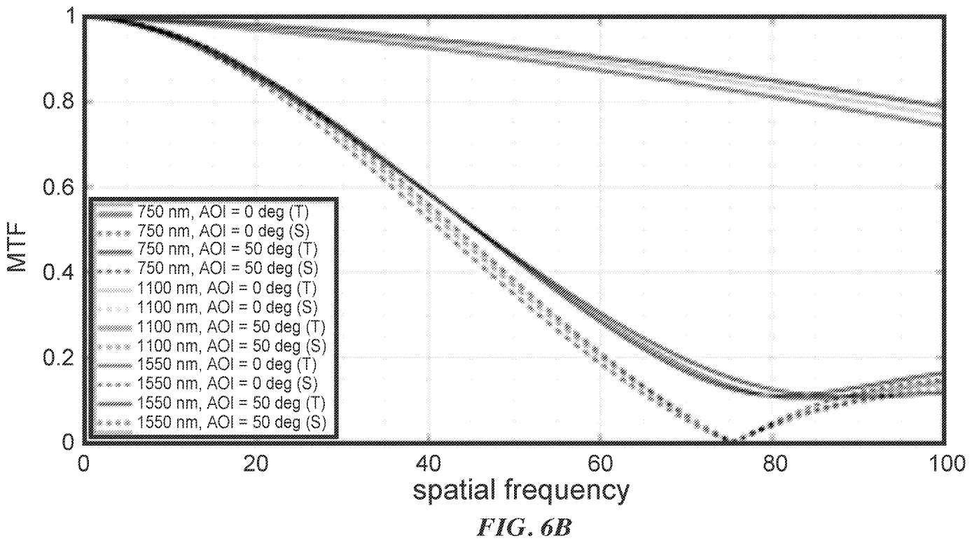

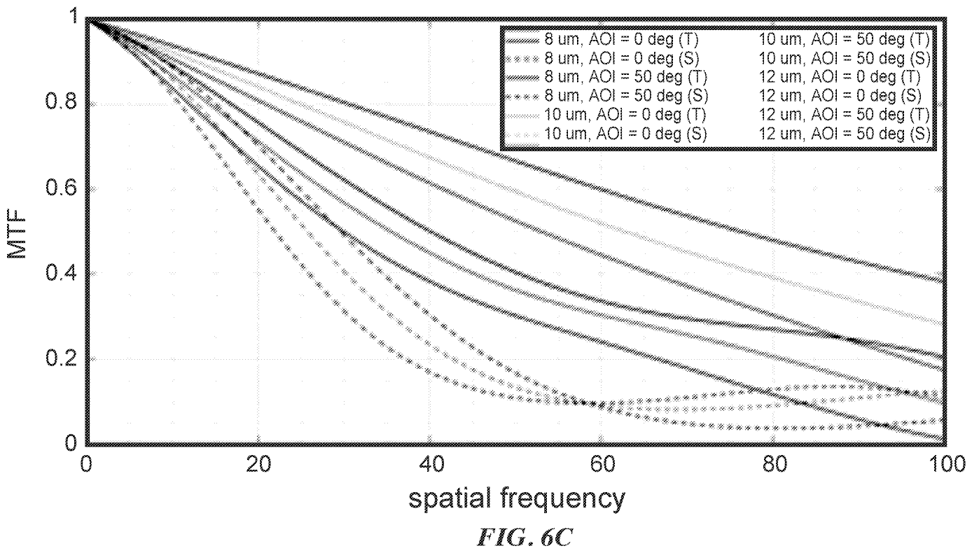

FIG. 6A illustrates another design of a hybrid meta-optical system 600 in which all substrate surfaces forming an objective lens are planar. In particular, metalens 1 and metalens 2 each comprise two flat metasurfaces 108 formed on opposing surfaces of each metalens. The metasurfaces 108 can differ from each other (e.g., have different meta-atom patterns). Flat spacers (spacer 1, spacer 2) are used between the metalenses and an image plane 650 (at which an image intensifier can be mounted). While the performance of this all-planar meta-optical system 600 is not as good as the curved meta-optical systems 200, 400 of FIG. 2 and FIG. 4A, it still outperforms traditional refractive-only designs (FIG. 5), yielding a near 100° FOV and compact form factor. Any of the objective optics in FIG. 2, FIG. 4A, and FIG. 6A can be used in the hybrid meta-optical system 200 of FIG. 2. FIG. 6B and FIG. 6C plot simulated MTFs for the hybrid metasurface optical system of FIG. 6A for near-infrared wavelengths (FIG. 6B) and mid-wavelength and long-wavelength infrared radiation (FIG. 6C).

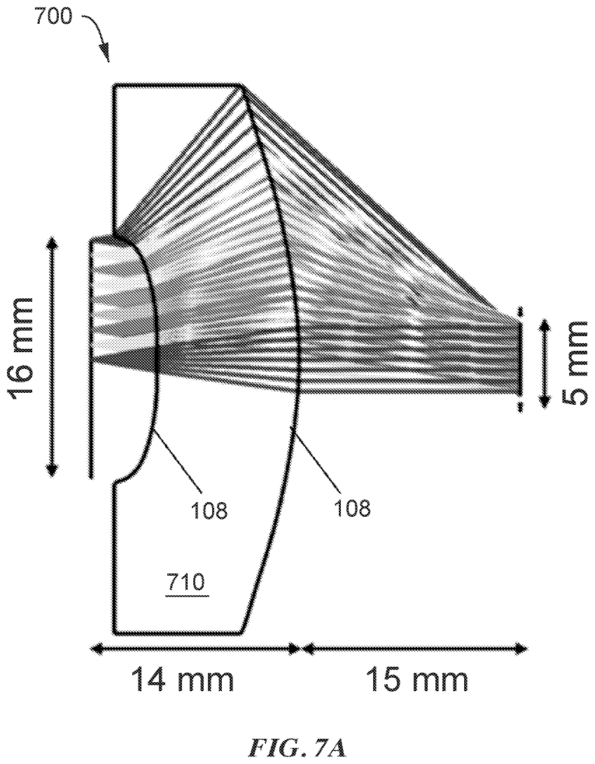

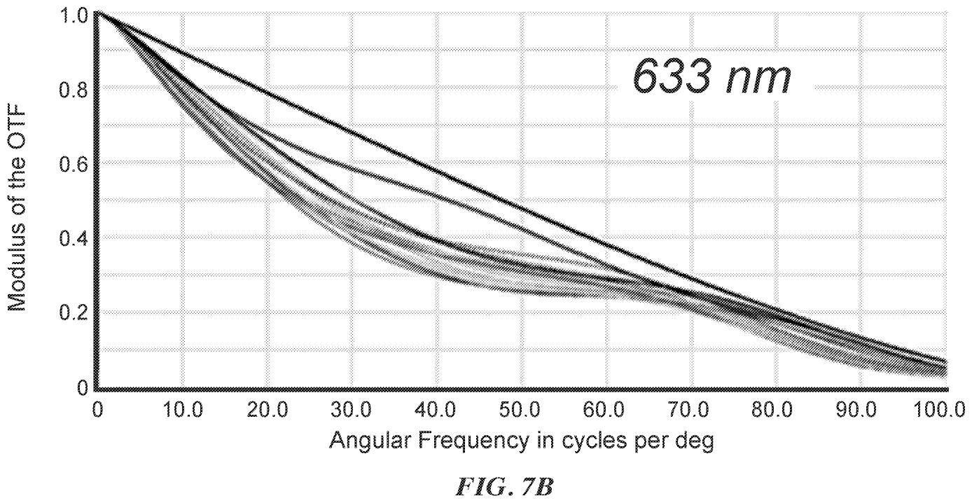

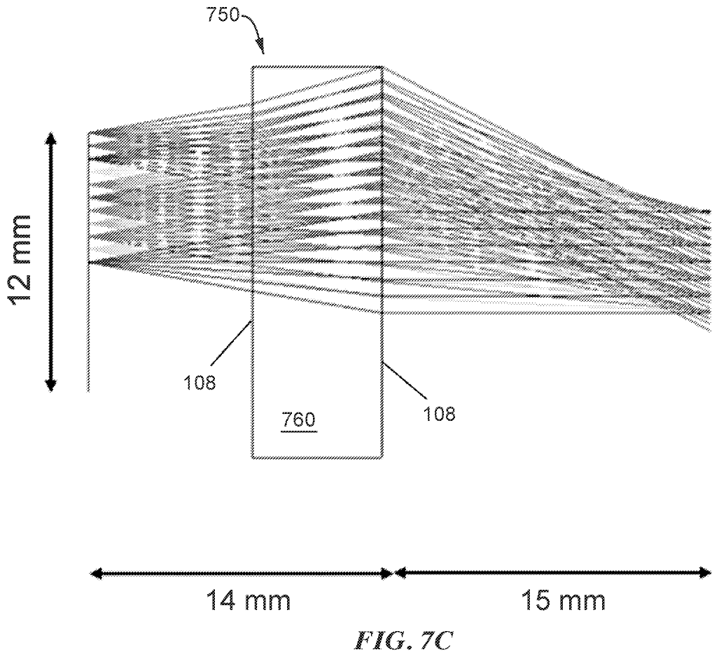

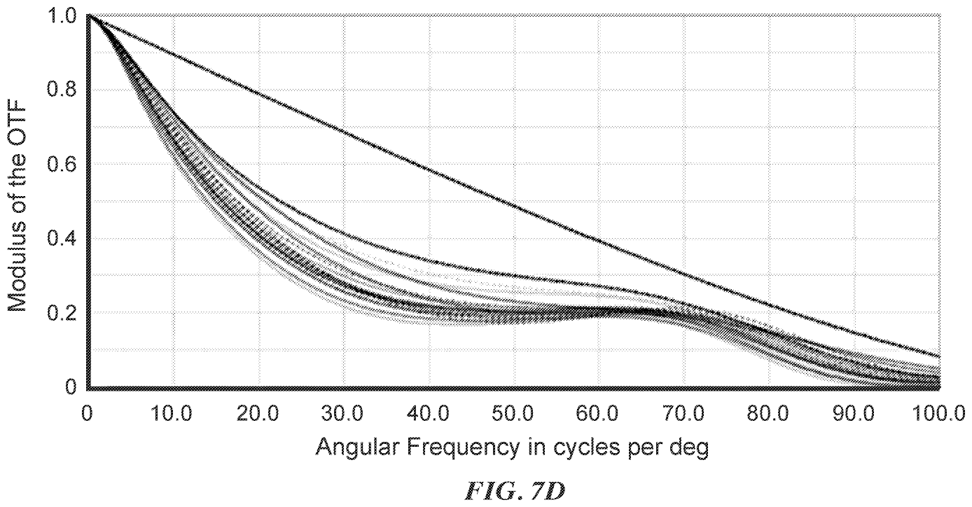

FIG. 7A and FIG. 7C depict two variations of an eyepiece hybrid meta-optical system 700, 750. For the implementation of FIG. 7A, two metasurfaces 108 are conformally integrated on non-planar surfaces of a curved substrate 710. A first surface of the curved substrate is concave and a second surface of the curved substrate 710 is convex. Near-diffraction-limited performance is achieved with a large FOV over 80°. The modulus of the optical transfer function is plotted in FIG. 7B for tangential rays (solid curves) and sagittal rays (dotted lines) at various off-axis distances from about 1 mm to about 8 mm.

For the implementation of FIG. 7C, a single planar substrate 760 is used with two planar metasurfaces 108 formed on each opposing flat surface of the substrate 760. A FOV of ~60° is obtained for the eyepiece meta-optic system 750. The modulus of the optical transfer function for the eyepiece of FIG. 7C is plotted in FIG. 7D for tangential rays (solid curves) and sagittal rays (dotted lines) at various off-axis distances from about 1 mm to about 6 mm. Both eyepiece designs of FIG. 7A and FIG. 7C are very compact involving only a single discrete component.

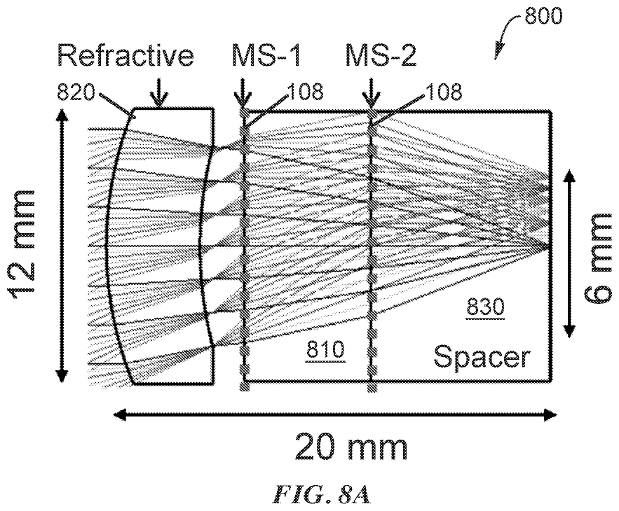

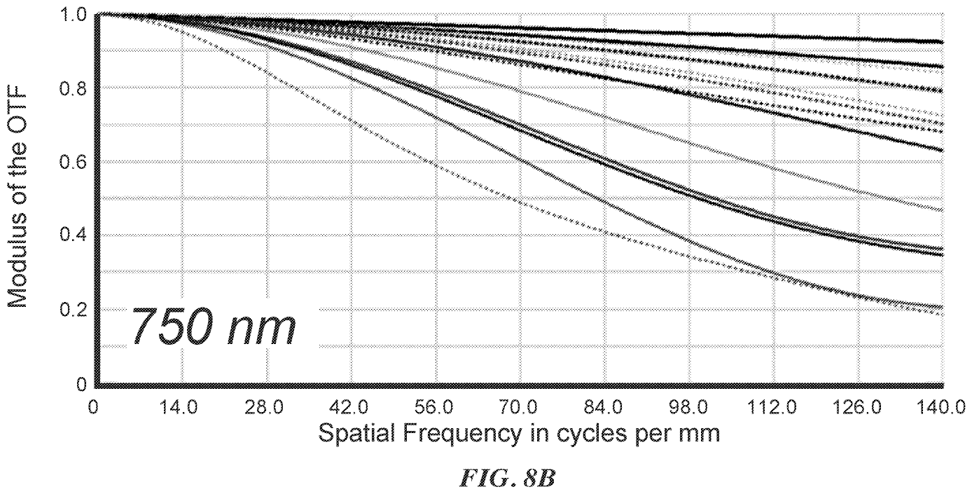

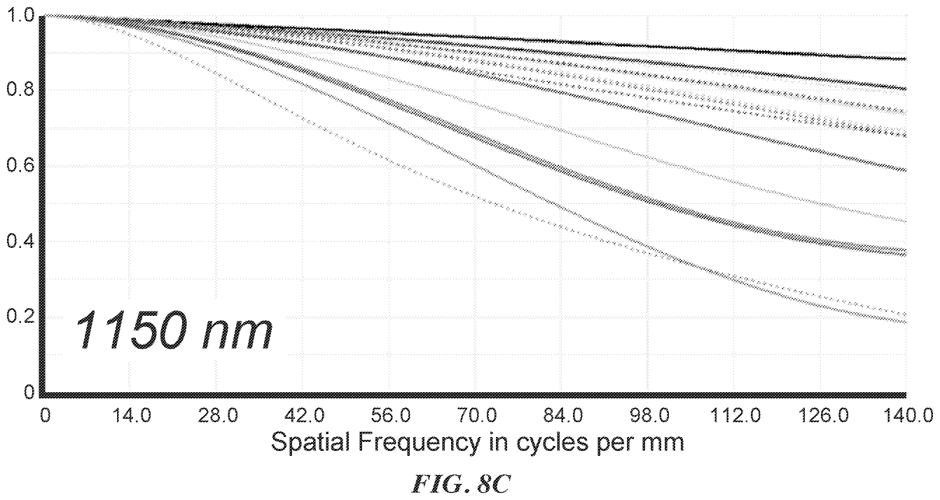

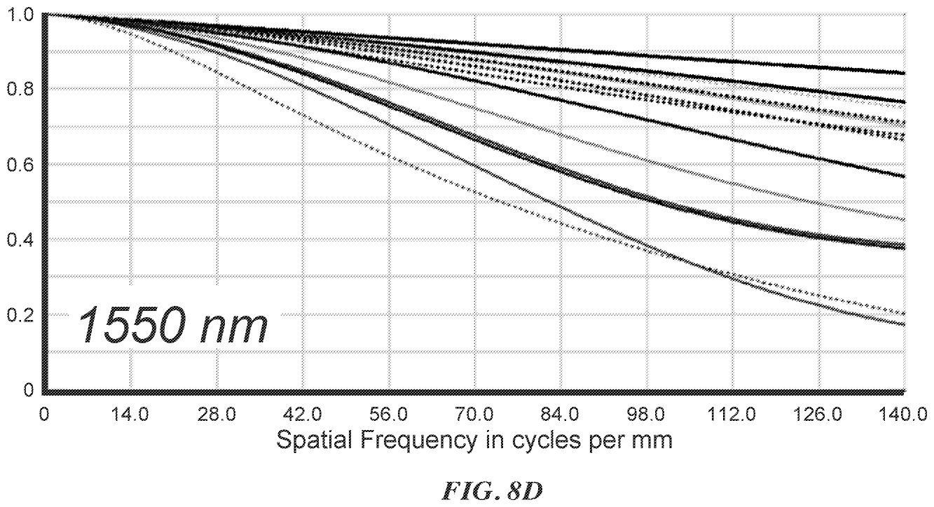

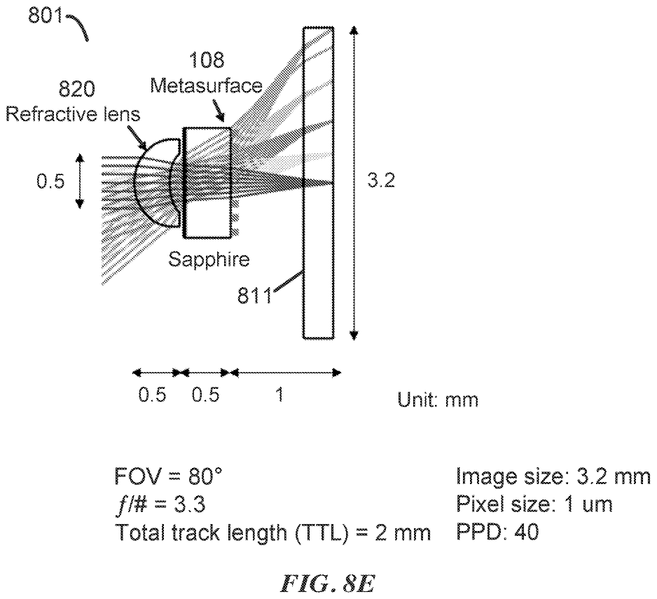

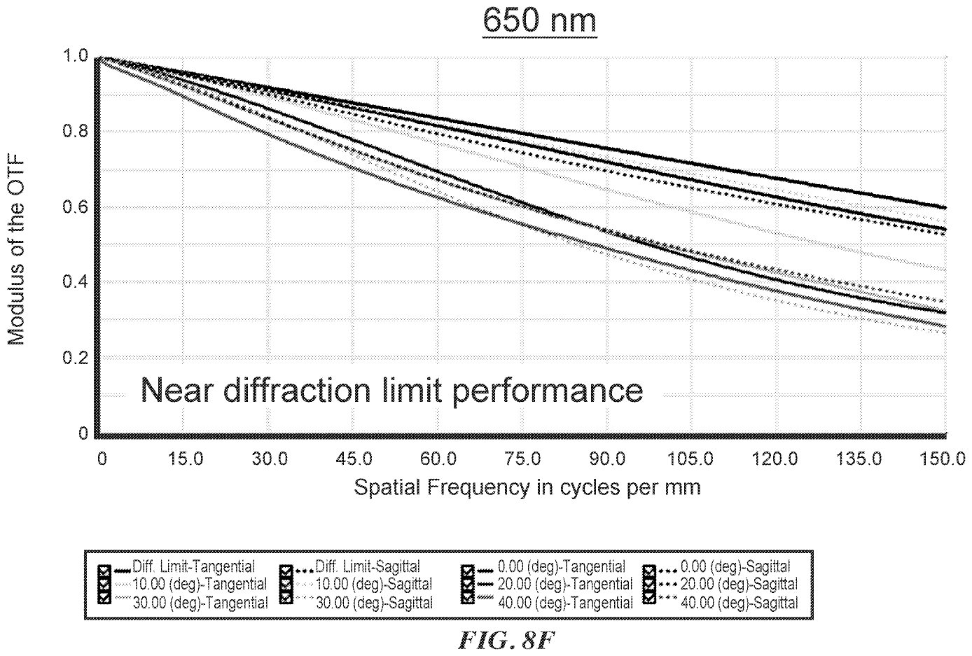

FIG. 8A through FIG. 8D illustrate that flat meta-optics can be combined with one or more refractive lens(es) to form a hybrid meta-optical system with improved optical performance. The hybrid meta-optical system 800 incorporates two flat metasurfaces 108 on a planar optic 810, one refractive lens 820, and a spacer 830, yielding a 60° FOV with high resolution (about 130 lp/mm or greater). The meta-optical system 800 has an f-number of 0.6. The total track length of the meta-optical system 800 can be no greater than 20 mm. The aperture of the meta-optical system is 12 mm. The resolution and FOV for the meta-optical system 800 can be improved by forming the two metasurfaces 108 on a curved optic instead of the planar optic 810. The modulus of the optical transfer function is plotted for three different wavelengths, tangential rays (solid curves), sagittal rays (dotted curves), and a range of incident angles from 0 degrees to 30 degrees in the plots of FIG. 8B, FIG. 8C, and FIG. 8D.

FIG. 8E depicts another implementation of a hybrid meta-optical system 801 that comprises one flat metasurface 108 on a planar optic, and one refractive lens 820. A glass plate 811 near the image plane can be a cover glass of the image sensor. The glass plate 811 can include an optical filter element. The hybrid meta-optical system 801 can operates at visible and/or near-IR wavelengths and yield a 80° FOV with near diffraction limit performance. The hybrid meta-optical system 801 has an f-number of 3.3. The design is ultracompact with a total track length of 2 mm. The modulus of the optical transfer function for the hybrid meta-optical system 801 is plotted in FIG. 8F for tangential rays (solid curves) and sagittal rays (dotted curves) over a range of incident angles from 0 degrees to 40 degrees.

### 5. Grin Meta-Optical Systems

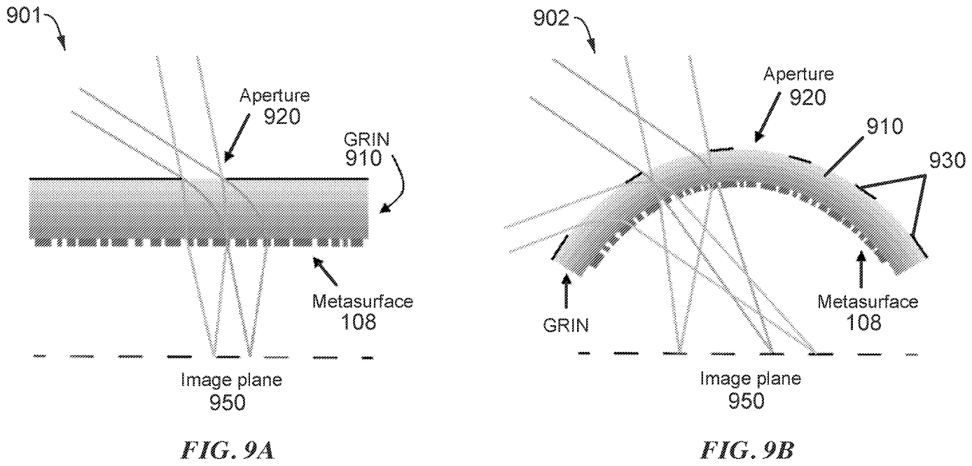

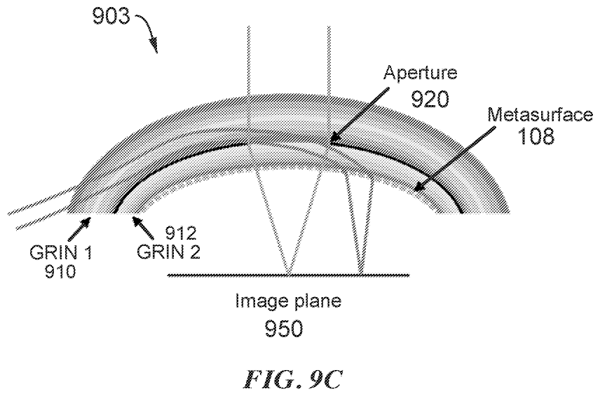

In additional embodiments, planar and/or non-planar metasurfaces 108 can be integrated with multi-layer optical structures or gradient-refractive-index (GRIN) structures. Some example GRIN meta-optical systems 901, 902, 903 are schematically illustrated in FIG. 9A through FIG. 9C. The GRIN meta-optical systems comprise one or more GRIN optics 910, 912 and at least one metasurface 108, which are conformally stacked together to form an integrated flat (FIG. 9A) or curved (FIG. 9B, FIG. 9C) GRIN meta-optical system. One or multiple apertures 920 may be integrated on, inside, outside, or in proximity to the GRIN meta-optical system. The apertures 920 can be formed by patterning an absorber 930 on a surface of the GRIN optic 910, for example. The absorber can comprise a metal or semiconductor.

In some implementations (such as in FIG. 9C), a first GRIN optic 910 and/or second GRIN optic 912 can include one or multiple apertures patterned on its surface(s). For the depicted example, the first GRIN optic 910 directs light at different incident angles towards a single aperture 920 via engineered index gradients. After the light passes through the aperture 920, it propagates through the second GRIN optic 912 (or homogeneous layer in some implementations) and is subsequently focused by the non-planar metasurface 108 towards an image sensor, which can be located at the system's image plane 950. In some cases, an additional GRIN optic or metasurface can be added between the depicted GRIN meta-optical system and the image plane 950 to further redirect/shape the light.

The application of metasurfaces to GRIN optics combines the capabilities of metasurfaces for in-plane wavefront shaping and GRIN optics for out-of-plane light guiding, within a highly compact form factor. The non-planar metasurface is judiciously designed to provide on-demand control of the wavefronts to realize desired optical performance and functionalities, e.g., wide-FOV imaging with reduced aberrations. The front GRIN layer replaces the bulky front lens group typically used in traditionally wide-angle lens assemblies (e.g., fisheye lenses) to capture light within an ultra-wide FOV beyond 180°. The intermediate GRIN optics can support additional tuning of the propagation of light. Compared to traditional optical components made of homogeneous media (e.g., lenses, free-space/plastic/glass spacers, etc.), the curved 3-D GRIN optics not only act as the light propagation medium but also wavefront shaping elements, and thereby significantly improve performance and reduce size when utilized with 2-D or 3-D metasurfaces.

Additionally, the conformal polymer film integration processes described above are suitable for transferring metasurfaces 108 to non-planar GRIN optics. The GRIN optic can serve as an optomechanical integration platform. For instance, thin-optic elements, apertures, shadow masks, and/or reflective coatings can be patterned on one or more polymer layers, stacked together, and applied onto the GRIN optic. Apertures may be used to confine the spatial and/or angular extents of an optical beam. Reflectors or reflective metasurfaces may be employed to fold a beam between certain layers to reduce the overall thickness of the optical system. Index contrasts of the GRIN optic (which may be implemented as multiple layers that form a stepwise gradient in refractive index) can also be employed to enable beam folding via total internal reflection (TIR).

The hybrid meta-optical devices described herein can further incorporate innovative zoom functionality without involving mechanical moving parts, a feature that can benefit endoscope systems. Non-mechanical parfocal zoom lenses using multi-functional optical metasurfaces have been demonstrated, which achieve large step zoom ratios (10×), reduced distortion, and diffraction-limited imaging quality. Such metasurfaces designed for zoom functionality, as described in International Patent Application PCT/US2022/077223 titled, “Multifunctional Metasurface Flat Optics” and filed on Sep. 29, 2022 (incorporated herein by reference in its entirety) can be used as metasurfaces for a hybrid meta-optical system described above. Using the hybrid curved meta-optics architecture, the zoom lens approach can achieve larger FOV/zoom ratios compared to flat architectures (e.g., switching between 240° and 20° FOVs for wide-angle and telephoto modes, respectively). Polarization-multiplexing zoom metalenses allow the metalens to toggle between the two modes under different polarizations of light. On the other hand, the image sensor used in such a system may be integrated with commercially-available, pixelated polarizer arrays aligned to each pixel on the image sensor. Consequently, the imager can simultaneously capture images of different polarizations generated by a polarization-multiplexed metalens. Such an approach enables camera architectures (e.g., miniaturized endoscope cameras) with high-performance imaging, ultra-wide FOV, non-mechanical zoom, and highly-compact form factors.

### 6. Conformal Metasurface-Enabled Display Systems

In additional implementations, thin-optic elements and their related fabrication processes (such as described above) can be used to improve the quality of display systems. Improved features include high-resolution, large field-of-view (FOV) image projection, improved eye relief and eye box, versatile display configurations, reduced size, weight and power (SWaP), etc. The thin non-planar optics can be in a variety of forms, such as sub-wavelength optics, metasurfaces, metamaterials, diffractive optical elements (DOE), holographic optical elements (HOE), wafer level optics (WLO), micro-optics, etc. The thin-optic elements can be generically applied in near-eye displays (NEDs) (which include head-mounted displays (HMDs) and heads-in displays (HIDs)) and heads-up displays (HUDs) for a wide variety of applications. For example, a front component coupled (e.g., optically and/or mechanically) with the display system can be a helmet visor, a windshield, a face shield, a cockpit canopy, eyeglass lenses, a goggle, an add-on component, etc. Display architectures and systems having non-planar thin-optic elements can feature large-area and/or multi-area, high-resolution image projection as well as co-integration of display and sensing systems.

### 6.1 NED Architectures and Systems Using Meta-Optics

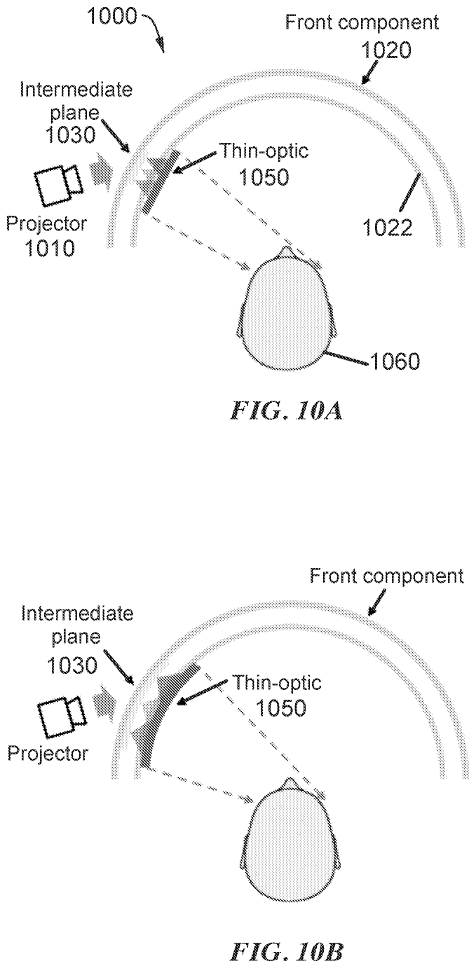

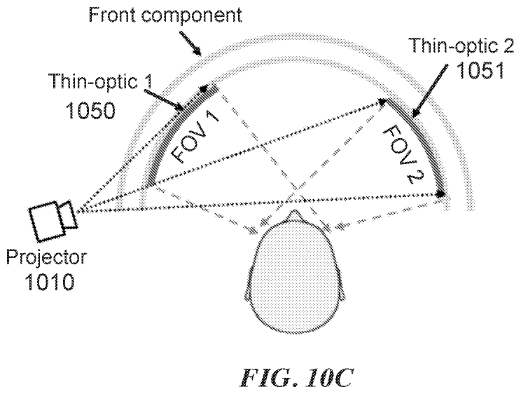

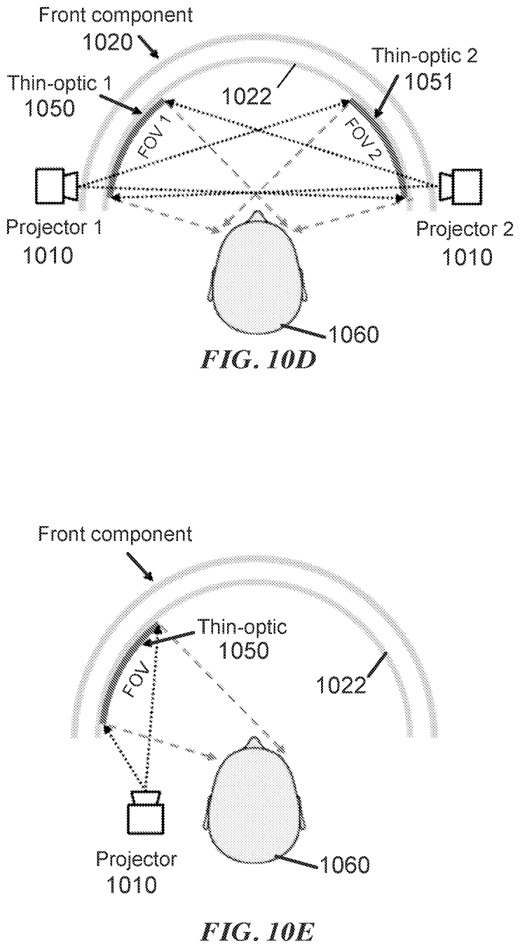

Near-eye displays (NEDs) can benefit from non-planar thin-optic elements and fabrication methods described above. The non-planar thin-optic elements may or may not include non-planar metasurfaces when implemented in a NED system. An example application can be integration with spacesuit helmets or AR/VR googles. FIG. 10A through FIG. 10E schematically illustrate NED systems 1000 comprising one or more projectors 1010 and one or more non-planar thin-optic elements 1050 that serve as redirecting optics and/or beam combiners. The projector 1010 projects one or multiple images towards a front optical component 1020 (e.g., a helmet or goggle visor). The thin-optic element(s) 1050 subsequently redirect the image towards the viewer 1060. When used as a combiner, the thin-optic element(s) 1050 can further combine the redirected/projected image with other information (e.g., the real-world scene, text, or images projected from other channels). The thin-optic element(s) 1050 can be in a variety of forms, such as meta-optic film(s) 150, metasurfaces 108, DOEs, HOEs, coatings, etc. The thin-optic element(s) 1050 can be configured for collimating, deflecting, and/or re-forming the image towards the viewer 1060. The thin-optic element(s) 1050 can be positioned on, inside, or outside the front optical component 1020 of the NED system 1000 or a NED system.

The thin-optic element(s) may also embed nano-particles, e.g., silver or gold nano-particles. The nano-particle embedded structures (e.g., meta-atoms) may be designed to selectively modulate the wavefront of certain wavelength(s) of light while transmitting others without modulation, thereby realizing functions such as an optical beam combiner.

NED systems can include one or two visor layers. As shown in FIG. 10A, an intermediate plane 1030 (at which an intermediate image projected by a projector, a scattering film, or a micro-display can be formed or located) can be located on one layer (e.g., the outer visor or front optical component 1020 of the visor). The thin-optic element(s) 1050 can be positioned on the same optical component or another optical component (e.g., the inner visor or rear optical component 1022 of the visor). As one example (FIG. 10A), a single thin-optic element 1050 can be configured on a flat substrate and assembled onto the inner helmet visor.

In another implementation (FIG. 10B), the thin-optic element 1050 and/or the intermediate plane 1030 can be non-planar. For example, the thin-optic element 1050 can be conformally integrated onto the curved surface of one of the helmet's visors. The intermediate plane 1030 can also be non-planar and located on one of the helmet's visors.

In yet another embodiment, the projector 1010 directly projects one or more images towards the front optical component 1020 without there being an intermediate plane. The thin-optic element(s) 1050 (which serve as, e.g., redirecting optics and/or combiners) are positioned on the front optical component 1020 and redirect the image(s) towards the viewer 1060. When used as a combiner, the thin-optic element(s) 1050 further combine the redirected/projected image(s) with other information (e.g., the real-world scene, text, or images projected from other channels). The thin-optic element(s) 1050 can again be in a variety of forms, such as meta-optical film(s) 150, metasurfaces 108, DOEs, HOEs, coatings, etc. The thin-optic element(s) 1050 can be designed for collimating, deflecting, and/or re-forming the image towards the viewer 1060.

In another example (FIG. 10C), one image projected from the projector 1010 is refracted by a first thin-optic element 1050 located at a first location on the visor and another image projected from the projector is reflected by a second thin-optic element 1051 located at a second location on the visor. The second thin-optic element 1051 can be different from the first thin-optic element 1050 to provide reflection rather than refraction. In another example (FIG. 10D), two images projected by two projectors 1010 are redirected by two thin-optic elements 1050, 1051 that serve as redirecting optics (or combiners) towards the viewer 1060.

The second thin-optic element 1051 can be the same as or different from the first thin-optic element 1050. In yet another example (FIG. 10E), a single projector 1010 projects an image from the inside of the helmet. The image can be redirected toward the viewer 1060 by a single non-planar thin-optic element 1050 disposed on the second optical component 1022 of the helmet. In some implementations, the single non-planar thin-optic element 1050 can combine the redirected image with the real-world scene, another image, or text from another source so that the viewer 1060 can view both from the same region of the second optical component 1022. For the implementations of FIG. 10A through FIG. 10B, the thin-optic elements 1050, 1051 can each comprise multiple thin-optic elements (e.g., stacked thin-optic elements) in some implementations. In some cases, each thin-optic element 1050, 1051 comprises at least one planar or non-planar metasurface 108, which may be implemented as a meta-optic film 150.

### 6.2 Wide-Angle Image Projection

Increasing the etendue of an image projector's optics (e.g., the aperture size and FOV) fundamentally improves the overall trade-offs among eye relief, eye box, and display FOV when the projector is used in display systems like those described herein. Traditional wide-angle optical systems (e.g., fisheye lenses) usually necessitate multi-lens assemblies to correct the induced optical aberrations, severely increasing the system complexity, size, weight, and cost. To avoid such issues, traditional multi-lens projectors can be replaced with a highly-compact meta-optic projector (also referred to as a meta-optical engine) that includes a wide-FOV meta-optical device.

FIG. 11A through FIG. 11C depict examples of such compact meta-optic projectors 1100, 1101, 1102. Any of the meta-optic projectors of these drawings can be used in the display systems of FIG. 10A through FIG. 10E. The meta-optic projectors comprise a meta-optic device 1110 that is optically coupled to an image source 1150 (such as a micro-display or other light source). In some implementations, the meta-optic device 1110 consists of one or more metasurfaces in combination with at least one thin optic, aperture, filter, or some combination thereof. It will be appreciated that the meta-optic projectors of FIG. 11A through FIG. 11C can be reconfigured and implemented as meta-optic imaging or sensing systems by replacing the image source 1150 with an image-capture device, such as a CMOS or CCD imaging array. For example, instead of projecting an image from the image source 1150, the apparatus is optically run in reverse to record an image from an image source. According to some implementations, the meta-optic projectors 1100, 1101, 1102 can be reconfigured as thin-optic projectors in which a metasurface is not used. Instead, one or more thin-optic elements can be used in place of the meta-optic device 1110.

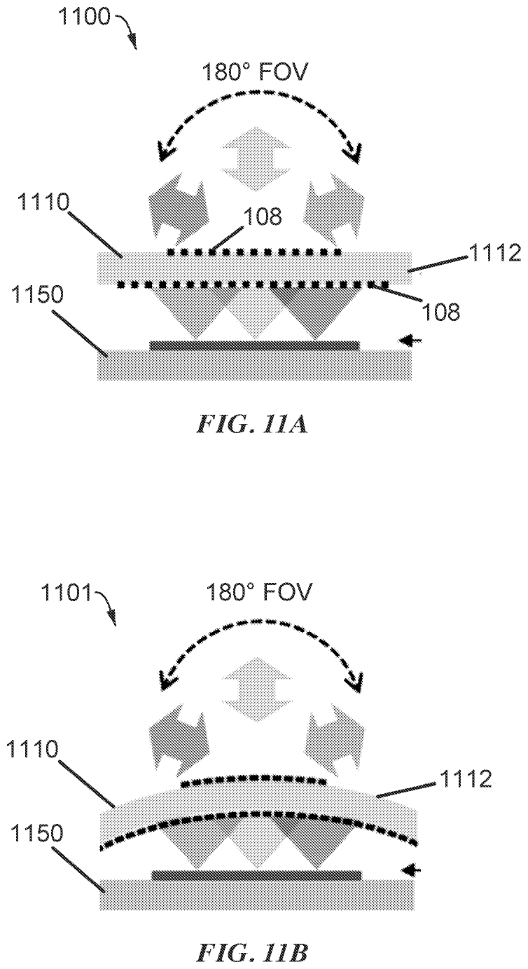

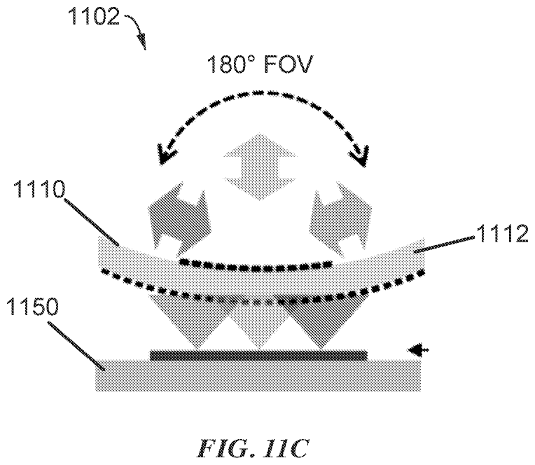

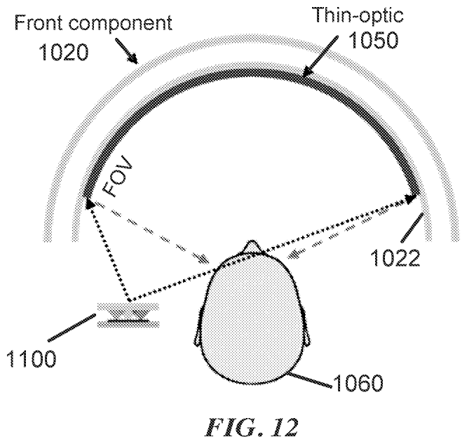

In FIG. 11A, the meta-optic projector 1100 comprises a flat meta-optic device 1110 and a micro-display for the image source 1150 (which would be replaced with an image sensor to make a meta-optic imager). The meta-optic device 1110 comprises a flat substrate 1112 and one or two metasurfaces 108, which can be positioned on top and/or bottom surfaces of the substrate 1112. Such an optical architecture can exhibit a panoramic 180° FOV or larger, high-resolution image projection over the entire FOV, and a highly compact optical architecture involving only a single meta-optic component, as described further in U.S. Pat. No. 10,979,635 titled “Ultra-Wide Field-of-View Flat Optics,” filed Jun. 8, 2020, which is incorporated by reference in its entirety. Curved substrates 1112 (illustrated in FIG. 11B and FIG. 11C) can be used to further improve the FOV, resolution, and/or facilitate device integration. When used in display systems described herein, such meta-optic projectors can dramatically enhance the etendue of the projected image with enlarged angular/spatial coverage and thereby improve the overall display performance. With a large FOV, multiple projected regions can also be realized from a single projector, allowing additional functions such as multiple screens, stereoscopic vision, etc. In some implementations, the thin-optic elements 1050, 1051 for redirecting and/or combining optical beams can be co-designed based on properties of the meta-optic projectors 1100, 1101, 1102 (e.g., to support an increased FOV and/or higher resolution). FIG. 12 depicts an example of a NED application in which the thin-optic element 1050 is expanded to support an increased FOV from any of the meta-optic projectors of FIG. 11A through FIG. 11C.

### 6.3 Arrayed Micro-Display Architecture

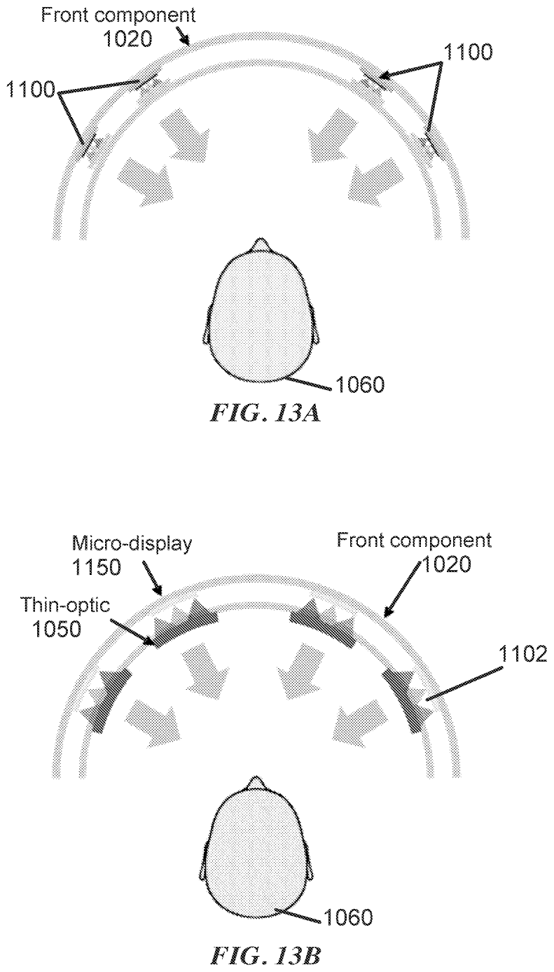

The highly-compact meta-optic projectors of FIG. 11A through FIG. 11C can also allow the direct integration of an array of such devices on or in close proximity to a component located in front of a user (such as a helmet visor or AR/VR goggle), as shown in FIG. 13A and FIG. 13B. The meta-optic projectors 1100 can be arranged in an array and may be configured to project images towards the viewer 1060, individually or collectively. For example, the array of meta-optic projectors 1100 may be configured to provide stereo display by projecting images with different contents, information, or light properties. The image source 1150 and/or meta-optic device 1110 (or thin-optic element) that are used in the projectors of FIG. 13A (flat depicted) and FIG. 13B (non-planar depicted) can be flat or non-planar. The image source 1150 and/or meta-optic device 1110 (or thin-optic element) may be positioned on, inside, or outside the front optical component 1020. For non-planar configurations, for example, flexible organic light-emitting diode (OLED) displays can be used as the micro-display for the image source 1150. Micro-LED displays disposed on a flexible or curved substrate may alternatively be used as the micro-display for the image source 1150.

### 6.4 Co-integrated Display and Sensing Devices

A combination of thin-optic projectors and thin-optic sensors can be co-integrated in an NED system, for example, to provide various functionalities (such as 3D sensing, eye tracking, facial and/or iris recognition, etc.).

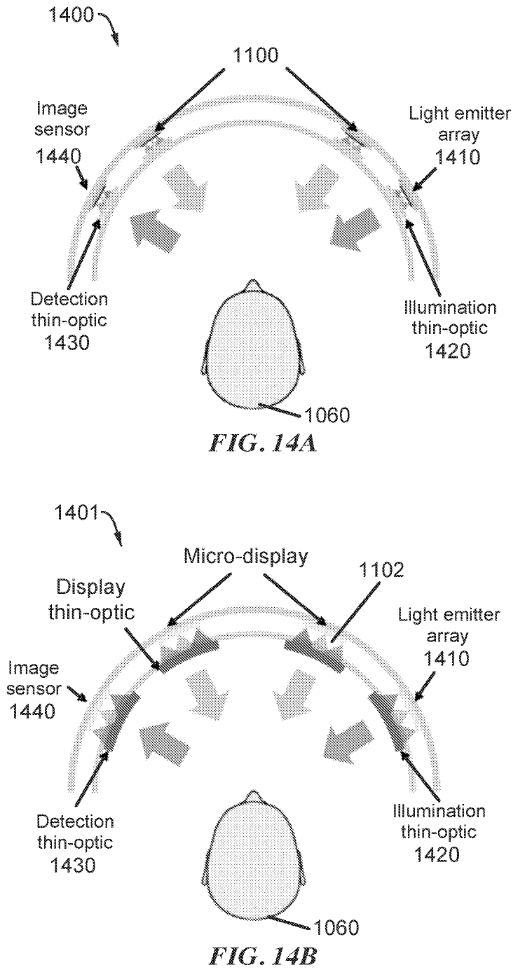

FIG. 14A and FIG. 14B depict examples of NED systems that combine image projection and image acquisition (or optical sensing). By replacing the micro-displays of some meta-optic projectors with image sensors/detectors and light emitter arrays while using similar meta-optics, the meta-optic projectors can be converted into meta-optic imagers or sensors. In example configurations, light emitters 1410 can be coupled with illumination thin-optic elements 1420 (e.g., meta-optics) to emit probing beams (red or darker arrows in FIG. 14A and FIG. 14B) towards an object/region (e.g., eye tissues for eye tracking/retinal imaging/iris recognition, face for facial recognition, etc.), while light reflected by the object is coupled by a detection thin-optic element 1430 onto an image sensor 1440 or at least one photodetector for data analysis. The illumination thin-optic elements 1420 can be configured to generate 2D/3D spot arrays or desired illumination patterns on the object/region of interest. In addition, a single light emitter (such as a single LED) or multiple light emitters can be coupled with an illumination thin-optic element 1420 (e.g., a meta-optic, DOE, or HOE designed as a holograph or spot generator) to generate 2D/3D spot arrays or illumination pattern onto the interested object/region.

FIG. 14A is a schematic illustration of a near-eye display system 1400 that integrates meta-optic projectors 1100 using flat substrates on which meta-atoms are located. The NED system 1400 can be adapted for eye tracking functionalities or eye-sensing functionalities. Eye-sensing functionalities include facial/iris recognition and general eye imaging (e.g., retina, pupil, palpebral, scleral, pars-planar, or iris, etc.). FIG. 14B is a schematic illustration of a near-eye display system 1401 that integrates meta-optic projectors 1102 and sensing/eye tracking functionalities using curved substrates on which meta-atoms are located. The green (lighter) arrows (located between the outer red (darker) arrows) indicate projected beams for image display functionality. The red arrows indicate probing and reflected beams for eye-tracking functionality.

Eye tracking systems typically measure the eyes'gazing point and position.

Video-based, optical eye tracking systems usually include a light source to produce a pattern that illuminates the eyes (usually in the near-IR) and an imager that images the eyes and the reflected beam/pattern. Information about eye movement can then be extracted by analyzing the captured image and reflected optical signals. For example, the corneal reflection and the center of the pupil can be used as features to determine the direction of gaze. Reflections from different eye tissues can also be used as features for tracking, such as the front of the cornea and the back of the lens. Features inside the eye (e.g., retinal blood vessels) can also be used for more precise tracking of eye movement.

To integrate eye tracking apparatus into an NED system, the system comprises at least one of: (1) one optical projector comprising an illumination thin-optic element 1420 (e.g., a meta-optic) and a light emitter 1410 (or emitter array) for illuminating the eye tissue (such as the iris, cornea, fundus, retinal blood vessels, pupil, etc.) with a probing beam with a prescribed illumination pattern, and (2) one optical imager including a detection thin-optic element 1430 and image sensor 1440 and/or at least one photodetector for collecting the reflected light and/or imaging the probed region. The system can further include (3) at least one display meta-optic projector 1100, 1102.

The illumination thin-optic elements 1420 can be designed to generate and image multiple spot arrays or illumination patterns on different tissues/objects or different locations in 3D space, so that the multiple spot arrays or illumination patterns can be tracked separately (e.g., by image acquisition apparatus and an image processor). The detection thin-optic element 1430 can be designed to capture images at different depth or tissues. The illumination thin-optic elements 1420 and detection thin-optic elements 1430 can be designed to illuminate and image, respectively, an object from different angles to generate a 3-D image, e.g., for stereo imaging.

The small form factor of the thin-optic architectures (e.g., meta-optics) also allows multiple projection and imaging sub-modules/sub-zones to be integrated and distributed at different locations within the same NED system, for example, as well as co-integration of the light emitter array and imager sensor.

An optical filter can be further integrated in the optical system (e.g., in front of the image sensor 1440) to pass or reject one or more desired ranges of wavelengths, polarization states, and/or angular components of light. Alternatively or additionally, any metasurface within the system can be designed to provide one or more desired filtering functionalities.

### 6.5 Demonstration of Transferring Optically-Active Features from a Planar Surface to a Non-Planar Surface

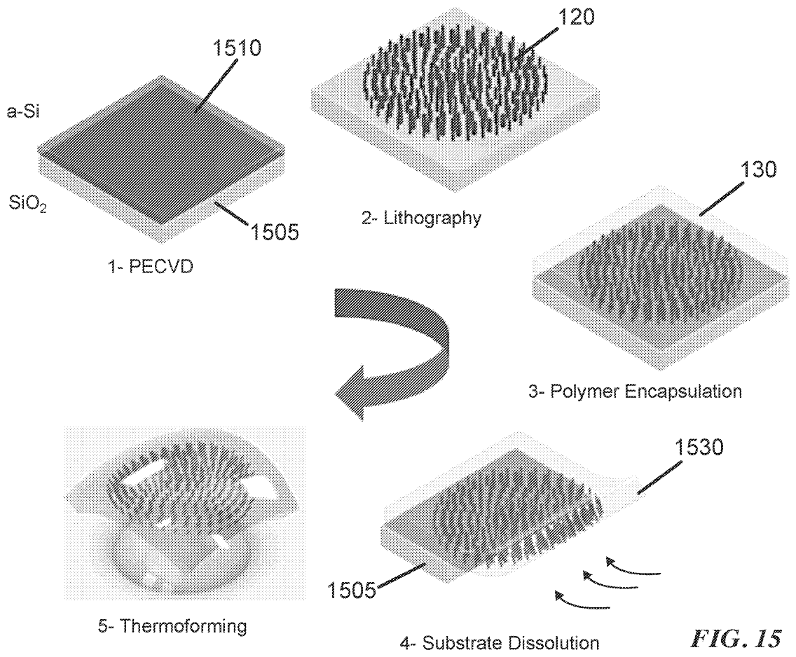

Optically-active features (meta-atoms in this example demonstration) were patterned on a planar surface and transferred to a curved (spherical) surface using the steps and apparatus depicted in FIG. 15. The process involved depositing a layer of amorphous silicon 1510 onto a substrate 1505 using plasma-enhanced chemical-vapor deposition (PECVD). The amorphous silicon 1510 was subsequently patterned into a plurality of meta-atoms 120 using lithography process steps. For this example, the meta-atoms 120 had a round pillar shape of different diameters and densities. The diameters of the pillars were less than 1 micrometer.

After the meta-atoms 120 were formed, they were encapsulated in a polymer. In one approach, polyethylene terephthalate glycol (PETG) dissolved in a 50:50 toluene/dichloromethane solvent solution was spin-coated onto the surface of the substrate 1505 to cover the meta-atoms 120. In a second approach, polyvinylchloride (PVC) dissolved in cyclohexanone was spin-coated onto the surface of the substrate 1505 to cover the meta-atoms 120. The spin-coated polymer was then annealed above its melting point to remove the solvent and release solvent vapors and obtain polymer layer with a refractive index of the initial undissolved polymer. The thickness of the resulting thermoplastic 130 was approximately 5 microns, though a thickness from 2 microns to 20 microns can be used.

To obtain a mechanically stable film of the thermoplastic 130, an industrially-manufactured polymer film can be laminated onto the spin coated polymer at 180 deg C (for PVC and PETG) using a roller and a PDMS interfacial layer to avoid adhesion between the roller and the laminated polymer film. The resulting multi-layer polymer film can have a highly uniform thickness that may be determined mostly by the applied polymer film.

For the illustrated demonstration, the substrate 1505 was dissolved in an etch to release the multi-layer polymer film 1530 and meta-atoms 120. In this example, the substrate was a phosphosilicate glass which has a very high etch rate in hydrofluoric acid. The etching solution was a 50:40:10 mix of isopropyl alcohol (IPA), deionized water, and hydrofluoric acid (HF). The IPA improves wetting of the glass to accelerate substrate dissolution. In an alternative implementation, the substrate 1505 can comprise a germanium layer that can be etched away with a hydrogen peroxide/ammonia solution and a suitable wetting agent.

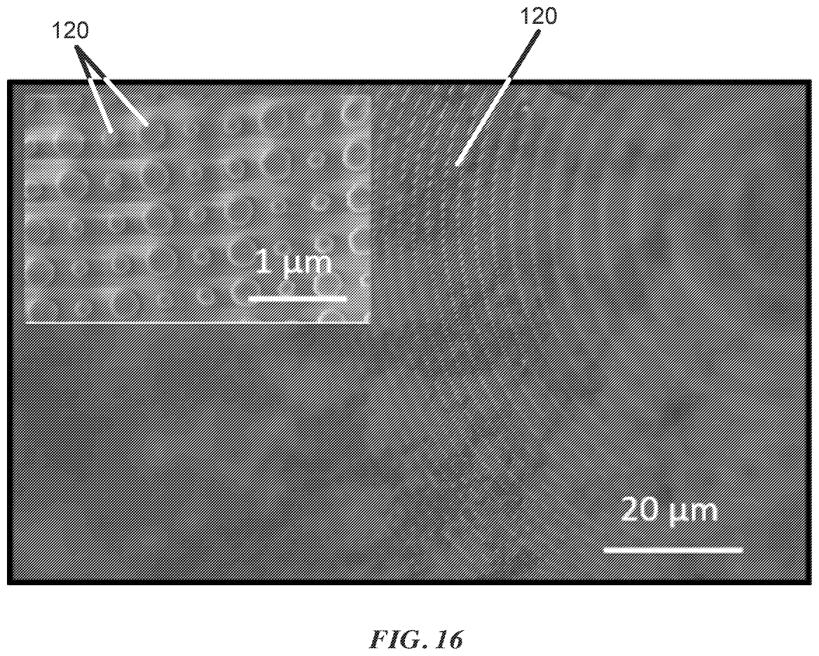

FIG. 16 shows microscope image (larger image) and scanning-electron-micrograph image (inset) of transferred features onto a curved surface. In this demonstration, pillars were patterned on a flat substrate and transferred to a curved surface with better than 99% yield following the process steps described in connection with FIG. 15. The meta-atoms 120 are transferred to the curved surface with high fidelity over large areas.

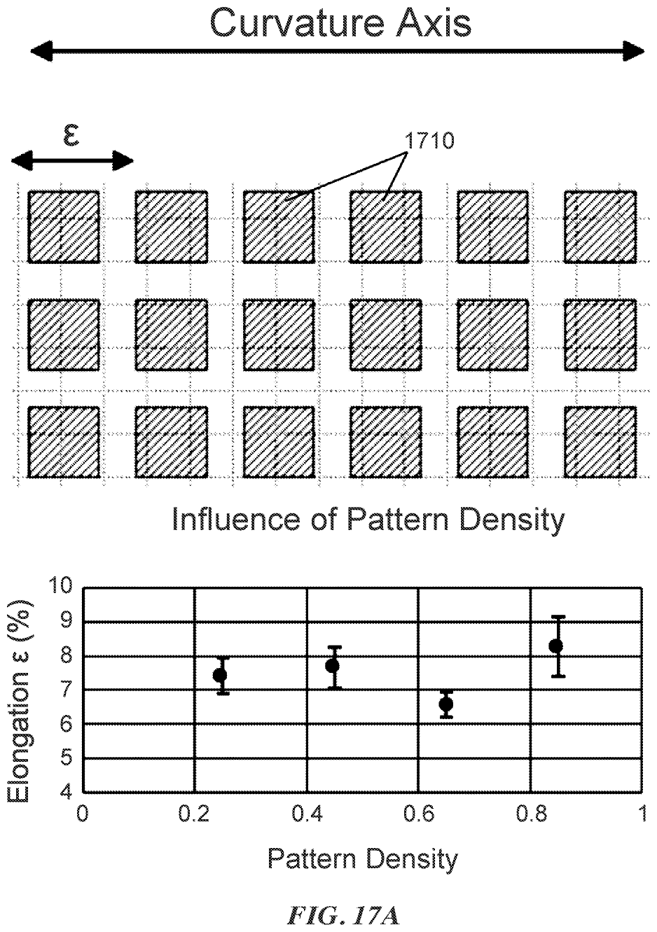

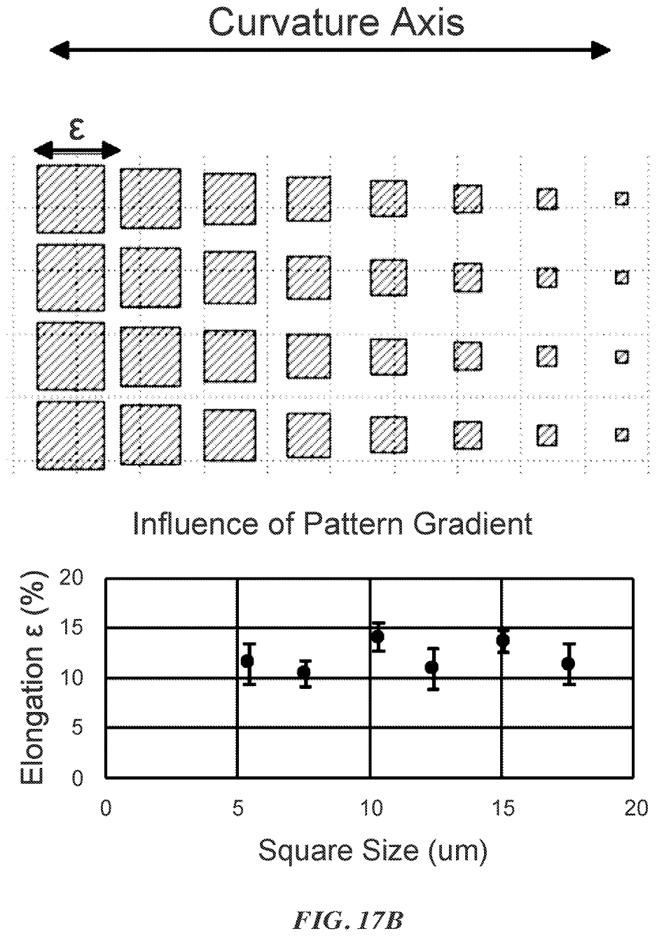

FIG. 17A and FIG. 17B show results of mechanical deformation studies for the thermoforming and transfer process. In these studies, micron-size squares 1710 were patterned across a flat substrate and then transferred to a cylindrically curved surface using the process steps described in connection with FIG. 15. The density of the pattern was varied (FIG. 17A) for one study and the size of the squares were varied (FIG. 17B) for another study. A capping layer (double-sided elastomeric tape) on the curved surface reduced the feature deformation.

The elongation of features remained below 15% across a wide range of feature sizes (square sizes ranging from 5 microns on a side to about 18 microns on a side) and remained below 10% across a wide range of pattern density (from about 20% pattern density to about 90% pattern density).

### 7. Multi-Level Meta-Optical Systems

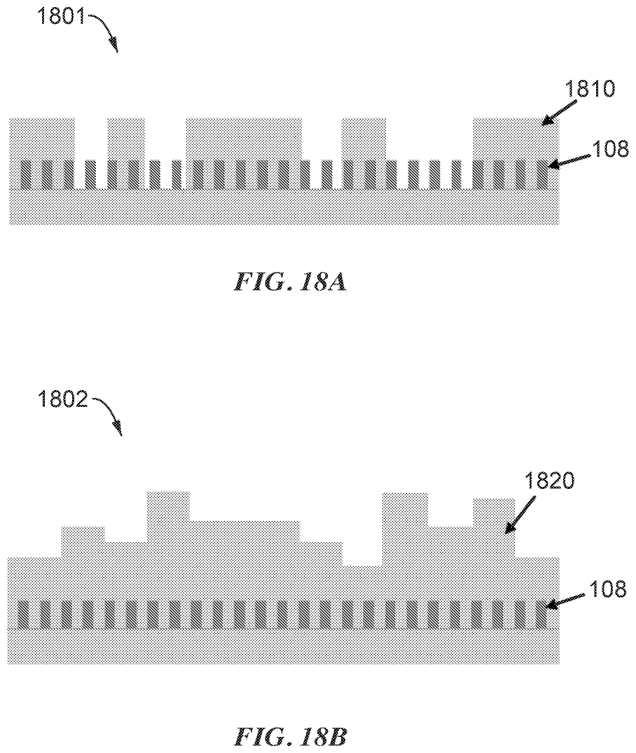

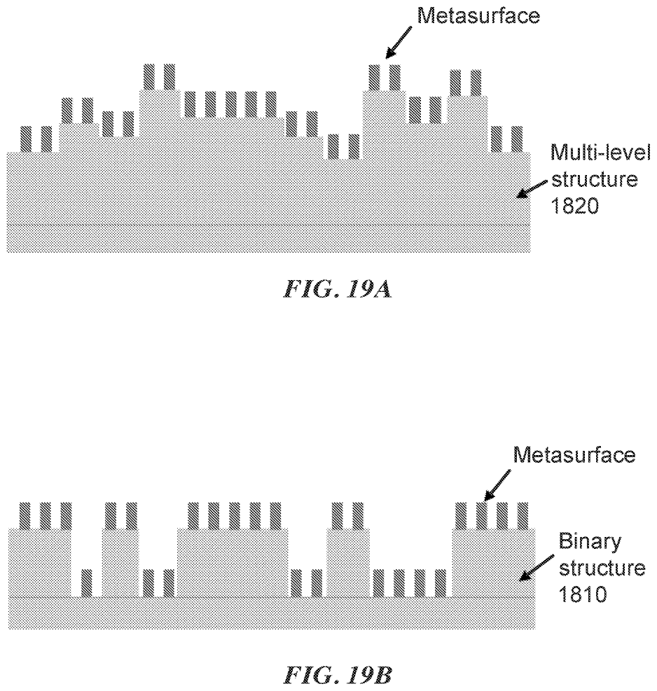

FIG. 18A illustrates an example of a hybrid meta-optical system 1801 in which a metasurface 108 is combined in the system with a binary optical element 1810. The binary optical element 1810 can be formed from a polymer or inorganic material, for example, that is deposited and patterned over the metasurface 108 using photolithography processes. The binary optical element 1810 can be a diffractive optical element (DOE) or a refractive optical element. The metasurface 108 and binary optical element 1810 are shown on a planar surface but could be transferred onto a non-planar surface using techniques described above.

FIG. 18B illustrates an example of a hybrid meta-optical system in which a metasurface 108 is combined in the system with a multi-level optical element 1820. The multi-level optical element 1820 can be formed from a polymer or inorganic material, for example, that is deposited and patterned over the metasurface 108 using grayscale photolithography processes, for example. The multi-level optical element 1820 can be a diffractive optical element (DOE) or a refractive optical element. The metasurface 108 and multi-level optical element 1820 are shown on a planar surface but could be transferred onto a non-planar surface using techniques described above.

In optical systems described above that include one or more metasurfaces, the metasurface(s) (alone or in combination with DOEs in some implementations) can be configured to modulate the phase, amplitude, polarization, and/or spectral properties of the incident light.

The optical systems that include one or more metasurfaces can also be configured to produce customizable modulations of the incident beam depending on the beam properties (e.g., angular, spatial, polarization, spectral properties, etc.). The optical systems that include one or more metasurfaces may also be configured to provide multiplexed functions, e.g., independent beam modulation of light of different wavelengths, polarization states, angle-of-incidence, etc.

In yet other examples of the hybrid configuration shown in FIG. 19A, the hybrid meta-optical system incorporates at least one planar or non-planar metasurfaces and one or multiple multi-level structures with varying thicknesses. As shown in FIG. 19A, a non-planar metasurface layer may be integrated on a non-planar structure, e.g., a multi-level refractive and/or diffractive optical element layer (DOE).

In yet other examples of the hybrid configuration shown in FIG. 19B, the hybrid meta-optical system incorporates at least one planar or non-planar metasurfaces and one or multiple binary structures with varying thicknesses. As shown in FIG. 19B, a non-planar metasurface layer may be integrated with a binary refractive and/or diffractive optical element layer (DOE).

In the embodiments described above, each unit of the multi-level structures may have different width, height, and/or geometries. The width of each unit may vary between 0.1 and 10000 times the wavelength. The height of each unit may vary between 0.1 and 10000 times the wavelength. The metasurface and multi-level structures may be made of any type of optical materials, such as glass, polymers, semiconductors, metal, etc. The multi-level structures may also be made of non-optical materials, e.g., to serve as a mechanical/optomechanical structure. They may further include coatings (e.g., dielectric and/or metallic coatings).

The hybrid multi-level meta-optics structures may be fabricated using similar approaches described in this invention for fabricating metasurfaces on non-planar substrates. In general, the metasurface and/the multi-layer structures may be fabricated using lithographic techniques, machining, or replication, in either subtractive or additive manner, or a combination of these methods. The lithographic approaches may involve deposition or growing of the metasurface layer and/or the multi-layer structure, patterning (e.g., using light-sensitive polymers), and etching, etc. Exemplary techniques in this category include, but not limited to, photolithography, multi-step lithography gray-scale lithography, electron beam direct writing, laser direct writing, etc. Machining approaches involve producing the metasurface and/or the multi-level structures by removing materials from a substrate via a controlled manner.

Exemplary techniques include, but not limited to, laser ablation, focused ion beam milling, diamond turning, mechanical ruling, etc. Replication approaches involve fabricating the multi-level structure and/or the metasurface in polymers, glasses, or other materials from a master/mold/stamp, which may be produced using the methods described above. Such techniques include, but not limited to, molding (e.g., injection molding), casting, thermal embossing, nanoimprint lithography, etc.

In some examples, the metasurface structures may be fabricated/integrated onto the multi-level structure either monolithically or hybridly. For monolith fabrication/integration, the meta-atoms and multi-level structures can be made of the same materials, and fabricated together using approaches such as molding, casting, embossing, nanoimprint, machining, laser direct writing, gray-scale lithography, nanoimprint lithography, multi-step photolithography, e-beam lithography, etc. For hybrid fabrication/integration, the meta-atoms and multi-level structures may be made of the same or different materials and the metasurface may be fabricated on the multi-level structure, using techniques such as molding, casting, embossing, nanoimprint, machining, laser direct writing, other lithographic methods, etc. For example, the metasurface may be integrated on a multi-level substrate using the similar thermoforming method as described in the application. In other approaches, a layer of the metasurface material may be first placed on the multi-level structure, which is subsequently patterned into meta-atom structures at different heights. Lithography tools (such as the 3D printers offered by Nanoscribe GmbH of Eggenstein-Leopoldshafen, Germany) may be utilized to fabricate such structures. In one example, direct writing or maskless lithography (e.g., laser direct writing, electron-beam lithography, etc.) may be utilized, in which the writing interface (according to the height of the multi-level structures) can be precisely adjusted during the patterning process. Such methods could also be used to fabricate the master/stamp/mold used the replication-based methods.

In all optical configurations described in the invention, the metasurface, DOE, refractive and/or reflective components may be configured to modulate the phase, amplitude, polarization, and/or spectral properties of the incident light. They can also be configured to produce customizable modulations of the incident beam depending on the beam properties (e.g., angular, spatial, polarization, spectral properties, etc.). They may also be configured to provide multiplexed functions, e.g., independent beam modulation of light of different wavelengths, polarization states, angle-of-incidence, etc.

Meta-optical elements and systems described herein can be implemented in various configurations, some of which are listed below. The meta-optical elements and systems can be manufactured using various processes, some of which are listed below.
(1) A method comprising: forming a thin-optic element on a planar surface of a first substrate, the thin-optic element comprising a plurality of patterned features arranged on the planar surface to provide at least one optical function for light comprising at least one specified wavelength incident on the thin-optic element, wherein the plurality of patterned features comprise one or both of micro-scale features and nanometer-scale features; encasing multiple surfaces of each patterned feature of the plurality of patterned features on the planar surface in a thermoplastic; delaminating the thermoplastic with the plurality of patterned features encased therein from the planar surface to form a thin-optic film; and applying the thin-optic film onto a non-planar surface of a second substrate.
(2) The method of (1), further comprising: pre-distorting a layout pattern for the plurality of patterned features to pre-distort the arrangement of the plurality of patterned features when forming the thin-optic element on the planar surface, wherein the pre-distortion of the layout pattern compensates for distortion of the thin-optic film when applied onto the non-planar surface.
(3) The method of (1) or (2), wherein encasing the plurality of patterned features comprises: spin-coating a solution containing the thermoplastic over the plurality of patterned features; and after the spin-coating, annealing the solution at a temperature above a glass transition temperature for the thermoplastic.
(4) The method of any one of (1) through (3), wherein the plurality of patterned features comprises meta-atoms and the thin-optic film is a meta-optic film.
(5) The method of any one of (1) through (4), wherein the thermoplastic comprises polyethylene terephthalate glycol (PETG).
(6) The method of any one of (1) through (5), wherein delaminating the thermoplastic comprises etching away a sacrificial layer of material located beneath the plurality of patterned features on the first substrate.
(7) The method of any one of (1) through (6), wherein applying the thin-optic film comprises: heating the thin-optic film; and compression molding the thin-optic film onto the non-planar surface.
(8) The method of any one of (1) through (7), wherein applying the thin-optic film comprises: heating the thin-optic film; and applying a vacuum to pull the thin-optic film onto the non-planar surface.
(9) The method of (8), wherein applying the vacuum pulls the thin-optic film upward, against gravity, onto the non-planar surface.
(10) The method of any one of (1) through (9), wherein the thin-optic film is a first thin-optic film, the method further comprising: stacking the first thin-optic film onto a second thin-optic film prior to applying the first thin-optic film and the second thin-optic film to the non-planar surface.
(11) The method of any one of (1) through (10), wherein the non-planar surface is the non-planar surface of a refractive optic such that the thin-optic film and the refractive optic form a non-planar hybrid thin-optic device.
(12) The method of any one of (1) through (10), wherein the non-planar surface is the non-planar surface of a graded refractive index lens.
(13) The method of any one of (1) through (10), wherein the non-planar surface is the non-planar surface of a visor in a helmet.
(14) An optical device comprising: an optically transparent substrate having a first surface and a second surface to pass light through the optically transparent substrate when the light is incident on the optically transparent substrate; and a thin-optic film adhered to the first surface of the optically transparent substrate, wherein the thin-optic film comprises: a thermoplastic encasing multiple surfaces of each feature of a plurality of patterned features, wherein the plurality of patterned features are arranged in the thermoplastic to provide at least one optical function for light comprising at least one specified wavelength incident on the thin-optic film, wherein the plurality of patterned features comprise one or both of micro-scale features and nanometer-scale features.
(15) The optical device of configuration (14), wherein the first surface of the optically transparent substrate is non-planar.
(16) The optical device of configuration (14) or (15), wherein the optically transparent substrate has a graded refractive index.
(17) The optical device of any one of configurations (14) through (16), wherein the plurality of patterned features comprises meta-atoms.
(18) The optical device of any one of configurations (14) through (17), in combination with an image source that is arranged to project an image onto the optical device.
(19) The combination of configuration (18), wherein the optically transparent substrate comprises a visor of a helmet or a goggle.
(20) The optical device of any one of configurations (14) through (19), in combination with an imager that is arranged to record an image received from the optical device.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the components so conjoined, i.e., components that are conjunctively present in some cases and disjunctively present in other cases. Multiple components listed with “and/or” should be construed in the same fashion, i.e., “one or more” of the components so conjoined. Other components may optionally be present other than the components specifically identified by the “and/or” clause, whether related or unrelated to those components specifically identified. Thus, as a non-limiting example, a reference to “A and/or B”, when used in conjunction with open-ended language such as “comprising” can refer, in one embodiment, to A only (optionally including components other than B); in another embodiment, to B only (optionally including components other than A); in yet another embodiment, to both A and B (optionally including other components), etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of components, and, optionally, additional unlisted items. Only terms clearly indicated to the contrary, such as “only one of” or “exactly one of,” or, when used in the claims, “consisting of,” will refer to the inclusion of exactly one component of a number or list of components. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more components, should be understood to mean at least one component selected from any one or more of the components in the list of components, but not necessarily including at least one of each and every component specifically listed within the list of components and not excluding any combinations of components in the list of components. This definition also allows that components may optionally be present other than the components specifically identified within the list of components to which the phrase “at least one” refers, whether related or unrelated to those components specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including components other than B); in another embodiment, to at least one, optionally including more than one, B, with no A present (and optionally including components other than A); in yet another embodiment, to at least one, optionally including more than one, A, and at least one, optionally including more than one, B (and optionally including other components); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method comprising:
forming a thin-optic element on a planar surface of a first substrate, the thin-optic element comprising a plurality of patterned features arranged on the planar surface to provide at least one optical function for light comprising at least one specified wavelength incident on the thin-optic element, wherein the plurality of patterned features comprise one or both of micro-scale features and nanometer-scale features;
encasing multiple surfaces of each patterned feature of the plurality of patterned features on the planar surface in a thermoplastic;
delaminating the thermoplastic with the plurality of patterned features encased therein from the planar surface to form a thin-optic film; and
applying the thin-optic film onto a non-planar surface of a second substrate.

2. The method of claim 1, further comprising:
pre-distorting a layout pattern for the plurality of patterned features to pre-distort the arrangement of the plurality of patterned features when forming the thin-optic element on the planar surface, wherein the pre-distortion of the layout pattern compensates for distortion of the thin-optic film when applied onto the non-planar surface.

3. The method of claim 1, wherein encasing the plurality of patterned features comprises:
spin-coating a solution containing the thermoplastic over the plurality of patterned features; and
after the spin-coating, annealing the solution at a temperature above a glass transition temperature for the thermoplastic.

4. The method of claim 1, wherein the plurality of patterned features comprises meta-atoms and the thin-optic film is a meta-optic film.

5. The method of claim 1, wherein the thermoplastic comprises polyethylene terephthalate glycol (PETG).

6. The method of claim 1, wherein delaminating the thermoplastic comprises etching away a sacrificial layer of material located beneath the plurality of patterned features on the first substrate.

7. The method of claim 1, wherein applying the thin-optic film comprises:
heating the thin-optic film; and
compression molding the thin-optic film onto the non-planar surface.

8. The method of claim 1, wherein applying the thin-optic film comprises:
heating the thin-optic film; and
applying a vacuum to pull the thin-optic film onto the non-planar surface.

9. The method of claim 8, wherein applying the vacuum pulls the thin-optic film upward, against gravity, onto the non-planar surface.

10. The method of claim 1, wherein the thin-optic film is a first thin-optic film, the method further comprising:
stacking the first thin-optic film onto a second thin-optic film prior to applying the first thin-optic film and the second thin-optic film to the non-planar surface.

11. The method of claim 1, wherein the non-planar surface is the non-planar surface of a refractive optic such that the thin-optic film and the refractive optic form a non-planar hybrid thin-optic device.

12. The method of claim 1, wherein the non-planar surface is the non-planar surface of a graded refractive index lens.

13. The method of claim 1, wherein the non-planar surface is the non-planar surface of a visor in a helmet.

14. An optical device comprising:
an optically transparent substrate having a first surface and a second surface to pass light through the optically transparent substrate when the light is incident on the optically transparent substrate; and
a thin-optic film adhered to the first surface of the optically transparent substrate, wherein the thin-optic film comprises:
a thermoplastic encasing multiple surfaces of each feature of a plurality of patterned features, wherein the plurality of patterned features are arranged in the thermoplastic to provide at least one optical function for light comprising at least one specified wavelength incident on the thin-optic film, wherein the plurality of patterned features comprise one or both of micro-scale features and nanometer-scale features.

15. The optical device of claim 14, wherein the first surface of the optically transparent substrate is non-planar.

16. The optical device of claim 14, wherein the optically transparent substrate has a graded refractive index.

17. The optical device of claim 14, wherein the plurality of patterned features comprises meta-atoms.

18. The optical device of claim 14, in combination with an image source that is arranged to project an image onto the optical device.

19. The combination of claim 18, wherein the optically transparent substrate comprises a visor of a helmet or a goggle.

20. The optical device of claim 14, in combination with an imager that is arranged to record an image received from the optical device.
